(19) United States
(12) Patent Application Publication
(10) Pub. No.: US 2024/0008312 A1
(43) Pub. Date: Jan. 4, 2024

(54) Organic Light Emitting Display Device

(71) Applicant: LG Display Co., Ltd., Seoul (KR)

(72) Inventor: Junghyun Lee, Paju-si (KR)

(21) Appl. No.: 18/209,812

(22) Filed: Jun. 14, 2023

(30) Foreign Application Priority Data
Jun. 30, 2022 (KR) 10-2022-0080595

(51) Int. Cl. H10K 59/121; H10K 59/126

(52) U.S. Cl. CPC H10K 59/1216; H10K 59/1213; H10K 59/126

(57) ABSTRACT

An organic light emitting display device using a hybrid type thin film transistor includes a conductive pattern disposed above a semiconductor pattern and having a higher etch resistance than an inorganic thin film, thus simplifying the manufacturing process of a hybrid type thin film transistor array substrate requiring a plurality of layers and improving the performance of the thin film transistor formed on the array substrate. In addition, configurations of various types of storage capacitors including conductive patterns are provided.

### CROSS REFERENCE TO RELATED APPLICATION

The present application claims the benefit under 35 USC § 119(a) of Republic of Korea Patent Application No. 10-2022-0080595, filed Jun. 30, 2022, in the Korean Intellectual Property Office, which is hereby incorporated by reference in its entirety.

### TECHNICAL FIELD

The present disclosure relates to an organic light emitting display device including a hybrid type thin film transistor, and in particular, to an organic light emitting display device capable of solving over-etching of a semiconductor pattern located at a bottom during a manufacturing process and having a conductive pattern instead of a doped region. In particular, the present disclosure relates to an organic light emitting display device capable of realizing a wide range of grayscale expression and a fast on/off operation by controlling an S-factor of a driving thin film transistor among a plurality of thin film transistors. In particular, the present disclosure provides structures of various storage capacitors each including a conductive pattern.

### BACKGROUND

Recently, with the development of multimedia, the importance of flat panel display devices is increasing. Therefore, flat panel displays such as liquid crystal displays, plasma displays, quantum dot displays, electrophoretic displays, and organic light emitting displays have been commercialized. Among these flat panel display devices, the organic light emitting display is currently widely used because of its high response speed, high luminance and wide viewing angle.

In such an organic light emitting display device, a plurality of pixels are arranged in a matrix form on a display panel, and each pixel includes a light emitting element portion represented by an organic light emitting layer and a pixel circuit portion represented by a thin film transistor. The pixel circuit portion includes a plurality of thin film transistors, such as a driving thin film transistor for supplying a driving current to operate an organic light emitting element and a switching thin film transistor for supplying a gate signal to the driving thin film transistor.

In addition, a gate driving circuit portion providing a gate signal to a pixel may be disposed in a non-display area of the organic light emitting diode display.

Since the plurality of thin film transistors are disposed in the pixel circuit portion and the gate driving circuit portion in a pixel, in particular, a sub-pixel as described above perform different functions, their electrical characteristics need to also be different. In order to make the electrical characteristics of the plurality of thin film transistors disposed in the pixel different, a plurality of thin film transistors made of different structures or different semiconductor materials are formed. However, when semiconductor material layers are formed in different layers and etched, the semiconductor material layers are exposed to different etching conditions so that a semiconductor material close to the substrate may be over etched compared to a semiconductor material far from the substrate.

### SUMMARY

To solve the above problem, the present disclosure is intended to stably secure the performance of a thin film transistor. In addition, the present disclosure is intended to provide various configurations of storage capacitors including conductive patterns for preventing or at least reducing over-etching of semiconductor material layers.

The present disclosure has been made to solve the above-mentioned problems occurring in the prior art and an object of the present disclosure is to propose a structure in which a doping process is not performed to form a source region and a drain region while reduce or prevent over-etching of a semiconductor pattern located in a lower portion in each pixel and another object of the present disclosure is to propose a structure capable of stably realizing the performance of thin film transistors included in the pixel. Still another object of the present disclosure is to provide various structures of storage capacitors including conductive patterns for reducing or preventing over-etching of semiconductor material layers. One or more embodiments of the present disclosure are to provide an organic light emitting display device, to provide an organic light emitting display device capable of solving over-etching of a semiconductor pattern located at a bottom during a manufacturing process and having a conductive pattern instead of a doped region, to provide an organic light emitting display device capable of realizing a wide range of grayscale expression and a fast on/off operation by controlling an S-factor of a driving thin film transistor among a plurality of thin film transistors, or to provide structures of various storage capacitors each including a conductive pattern.

According to an aspect of the present disclosure, an organic light emitting display device includes a substrate including a display area and a non-display area disposed in vicinity of the display area, an upper buffer layer disposed on the substrate, a first thin film transistor including a first semiconductor pattern disposed under the upper buffer layer and a first gate electrode, a second thin film transistor including a second semiconductor pattern disposed above the upper buffer layer and a second gate electrode, a conductive pattern disposed above at least one of the first semiconductor pattern and the second semiconductor pattern, and a storage capacitor connected to the second thin film transistor.

The second thin film transistor may include a second source electrode and a second drain electrode disposed above the upper buffer layer and a second light blocking pattern disposed below the second semiconductor pattern and connected to one of the second source electrode and the second drain electrode.

The second light blocking pattern may be disposed in the upper buffer layer, the second gate electrode may be disposed above the second semiconductor pattern with a second gate insulating layer interposed therebetween, and a parasitic capacitance between the second light blocking pattern and the second semiconductor pattern may be greater than a parasitic capacitance between the second gate electrode and the second semiconductor pattern.

The first thin film transistor may be disposed in at least one of the display area and the non-display area, and the second thin film transistor may be disposed in the display area.

The first semiconductor pattern may be configured as a polycrystalline semiconductor pattern, and the second semiconductor pattern may be configured as an oxide semiconductor pattern.

A first sub-upper buffer layer constituting a part of the upper buffer layer may be disposed under the second light blocking pattern, and a second sub-upper buffer layer constituting a part of the upper buffer layer may be disposed above the second light blocking pattern.

The storage capacitor may include a first electrode of the storage capacitor disposed in the same layer as the first gate electrode, a second electrode of the storage capacitor disposed in the same layer as the second light blocking pattern, and a third electrode of the storage capacitor disposed in the same layer as the conductive pattern.

The storage capacitor may further include a fourth electrode of the storage capacitor disposed in the same layer as the second gate electrode.

The storage capacitor may further include a fifth electrode of the storage capacitor disposed between the first electrode of the storage capacitor and the second electrode of the storage capacitor.

The storage capacitor may further include a second electrode of the storage capacitor disposed in the same layer as the second light blocking pattern, a third electrode of the storage capacitor disposed in the same layer as the conductive pattern, a fourth electrode of the storage capacitor disposed in the same layer as the gate electrode, and a sixth electrode of the storage capacitor disposed in the same layer as the second source electrode.

The second gate electrode and the second source electrode may be disposed in different layers.

The second gate electrode and the second source electrode may be disposed in the same layer as each other.

Further, sub-storage capacitances formed between adjacent electrodes among the first electrode of the storage capacitor to the fifth electrode of the storage capacitor may be connected in parallel to each other.

Further, electrodes of the storage capacitor other than the first electrode of the storage capacitor may be electrically connected to each other.

The third electrode of the storage capacitor may have a structure in which the second semiconductor pattern and the conductive pattern are stacked.

The third electrode of the storage capacitor may be connected to the other electrode of the storage capacitor through a contact hole, and the third electrode of the storage capacitor may be in contact with a side of the contact hole.

The first thin film transistor may further include a first source electrode and a first drain electrode, the second thin film transistor may further include a second source electrode and a second drain electrode, and the first source electrode, the first drain electrode, the second source electrode, the second drain electrode and the second gate electrode may be disposed in the same layer.

The first thin film transistor may further include a first source electrode and a first drain electrode, the second thin film transistor may further include a second source electrode and a second drain electrode, and the first source electrode and the first drain electrode may be disposed in the same layer as the second light blocking pattern.

The second source electrode and the second drain electrode may be disposed in the same layer as the second gate electrode.

The second thin film transistor may be a thin film transistor that drives a unit pixel disposed in the display area.

In the organic light emitting diode display according to the present disclosure, conductive patterns are additionally disposed above the source and drain regions of the oxide semiconductor pattern to allow contact holes having different depths to be formed at once when contact holes are formed such that the source region and the drain region are in contact with the source electrode and the drain electrode, respectively, thereby reducing the use of masks. In addition, in the prior art, a process of doping an oxide semiconductor pattern with dopant ions or a process of allowing particles to be collided with the oxide semiconductor pattern needs to be performed. However, according to the present disclosure, it is possible to omit a process for allowing oxide semiconductor pattern conductive to have conductivity by adding a conductive pattern above the source region and the drain region to enable the conductive pattern to serve as the source region and the drain region.

In addition, according to the present disclosure, a process of making the source region and drain region conductive may be omitted, the gate electrode, the source electrode, and the drain electrode can be disposed in the same layer, thereby reducing the use of masks. In addition, as it includes a conductive pattern for preventing etching, various types of storage capacitors using the conductive pattern are proposed.

### BRIEF DESCRIPTION OF THE DRAWINGS

FIG. 1A is a schematic block diagram of an organic light emitting display device according to one embodiment of the present disclosure.

FIG. 1B is a cross-sectional view of the display device taken along line “G-G” in FIG. 1A according to one embodiment of the present disclosure.

FIG. 2 is a schematic block diagram of a sub-pixel of an organic light emitting display device according to one embodiment of the present disclosure.

FIG. 3 is a circuit diagram of a sub-pixel of an organic light emitting display device according to one embodiment of the present disclosure.

FIG. 4A is a cross-sectional view illustrating an example of one thin film transistor disposed in a gate driving circuit portion of a non-display area, and a driving thin film transistor, a switching thin film transistor and a storage capacitor disposed in a display area, according to an embodiment of the present disclosure.

FIG. 4B is an enlarged cross-sectional view of area B of FIG. 4A according to one embodiment of the present disclosure.

FIG. 4C is a cross-sectional view of a bending area of a non-display area according to an embodiment of the present disclosure.

FIG. 4D is a cross-sectional view illustrating another configuration of a storage capacitor in area B illustrated in FIG. 4A according to one embodiment of the present disclosure.

FIG. 4E is a cross-sectional view illustrating still another configuration of a storage capacitor in area B illustrated in FIG. 4A according to one embodiment of the present disclosure.

FIG. 4F is a cross-sectional view illustrating still another configuration of a storage capacitor in area B illustrated in FIG. 4A according to one embodiment of the present disclosure.

FIG. 5A is a cross-sectional view illustrating an example of one thin film transistor disposed in a gate driving circuit portion of a non-display area, and a driving thin film transistor, a switching thin film transistor and a storage capacitor disposed in a display area, according to another embodiment of the present disclosure.

FIG. 5B is a cross-sectional view illustrating still another configuration of a storage capacitor in area B illustrated in FIG. 5A according to one embodiment of the present disclosure.

FIG. 5C is a cross-sectional view illustrating still another configuration of a storage capacitor in area B illustrated in FIG. 5A according to one embodiment of the present disclosure.

FIG. 5D is a cross-sectional view illustrating another configuration of a storage capacitor in area B illustrated in FIG. 5A according to one embodiment of the present disclosure.

FIG. 6A is a cross-sectional view illustrating an example of one thin film transistor disposed in a gate driving circuit portion of a non-display area, and a driving thin film transistor, a switching thin film transistor and a storage capacitor disposed in a display area, according to another embodiment of the present disclosure.

FIG. 6B is a cross-sectional view illustrating still another configuration of a storage capacitor in area B illustrated in FIG. 6A according to one embodiment of the present disclosure.

### DETAILED DESCRIPTION

Reference will now be made in detail to example embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and a method of achieving them will become apparent with reference to the embodiments described below in detail in conjunction with the accompanying drawings. However, the present disclosure is not limited to the embodiment to be disclosed below and is implemented in different and various forms. The embodiments bring about the complete disclosure of the present disclosure and are only provided to make those skilled in the art understand the scope of the present disclosure.

The shapes, sizes, ratios, angles, numbers, and the like illustrated in the accompanying drawings for describing various embodiments of the present disclosure are merely examples, and the present disclosure is not limited thereto. Like reference numerals refer to like elements throughout. Further, in the following description of the present disclosure, a detailed description of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise. Any implementation described herein as an “example” is not necessarily to be construed as preferred or advantageous over other implementations.

Elements are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

In describing temporal relationship, terms such as “after,” “subsequent to,” “next to,” “before,” and the like may include cases where any two events are not consecutive, unless the term “immediately” or “directly” is explicitly used.

In describing elements, terms such as “first” and “second” are used, but the elements are not limited by these terms. The terms are used only for distinguishing between one component and other components. Accordingly, as used herein, a first element may be a second element within the technical idea of the present disclosure.

In describing elements of the present disclosure, when an element or layer is described as being “connected,” “coupled,” or “adhered” to another element or layer, the element or layer can not only be directly connected, coupled, or adhered to another that other element or layer, but also be indirectly connected, coupled, or adhered to that other another element or layer with one or more intervening elements or layers “disposed,” or “interposed” between the elements or layers, unless otherwise specified.

When “comprise,” “have,” and “include” described in the present specification are used, another part may be added unless “only” is used. An element described in a singular form is intended to include a plurality of elements, and vice versa, unless the contrary context clearly indicates otherwise.

The term “at least one” should be understood as including any and all combinations of one or more of the associated listed items. For example, the meaning of “at least one of a first item, a second item, and a third item” encompasses the combination of all three listed elements, combinations of any two of the three elements, as well as each individual element, the first element, the second element, and the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Hereinafter, an organic light emitting display device according to an embodiment of the present disclosure will be described with reference to the accompanying drawings.

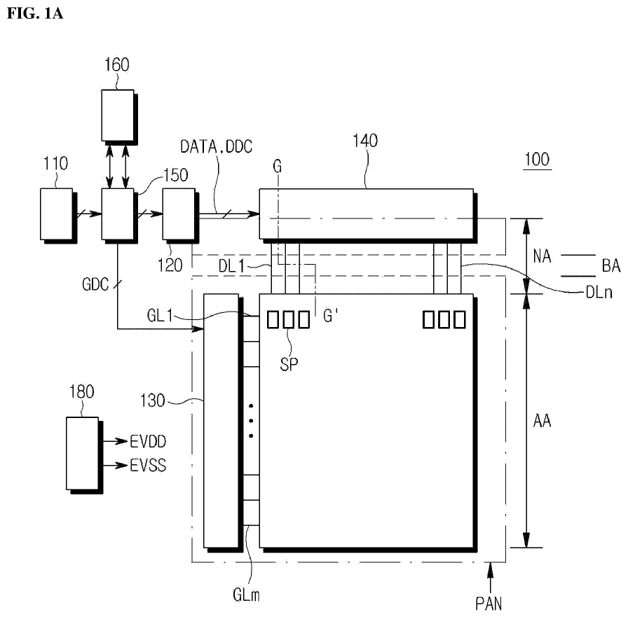

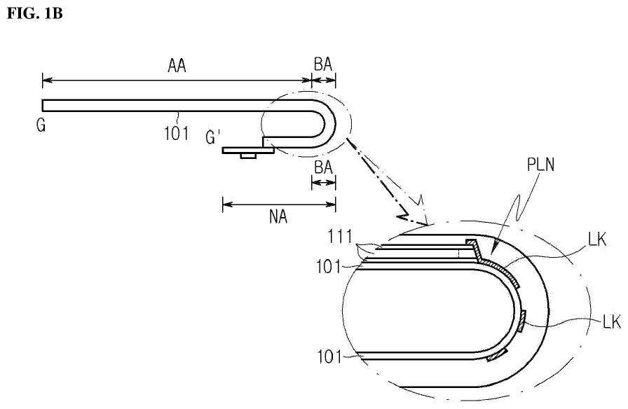

FIG. 1A is a schematic block diagram of an organic light emitting display device 100 according to one embodiment of the present disclosure, and FIG. 1B is a cross-sectional view of the organic light emitting diode display 100 taken along line G-G′ in FIG. 1A according to one embodiment of the present disclosure. All the components of the organic light emitting display device according to all example embodiments of the present disclosure are operatively coupled and configured.

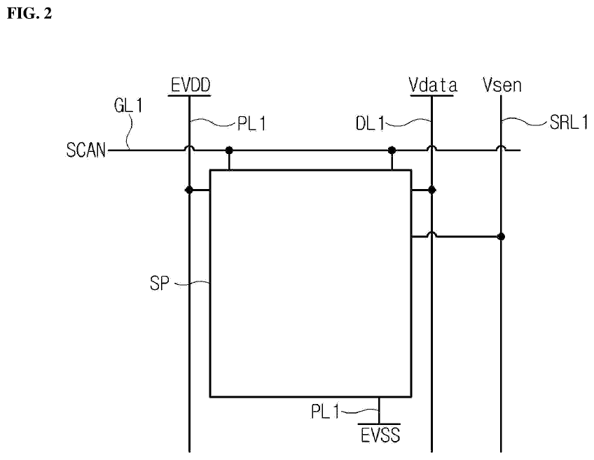

FIG. 2 is a schematic block diagram of a sub-pixel (SP) shown in FIG. 1A according to one embodiment of the present disclosure.

Referring to FIG. 1A, an organic light emitting display device 100 may be configured by including a display panel PAN in which an image processing unit 110, a deterioration compensation unit 150, a memory 160, a timing controller 120, a data driver 140, a power supply 180 and a gate driver 130 are formed. In particular, a non-display area NA of the display panel PAN may include a bending area BA. The display panel PAN may be folded in the bending area BA to reduce a bezel.

The image processing unit 110 (e.g., a circuit) may output driving signals for driving various devices together with image data supplied from the outside. For example, the driving signals output from the image processing unit 110 may include a data enable signal, a vertical synchronization signal, a horizontal synchronization signal, a clock signal and the like.

The deterioration compensation unit 150 (e.g., a circuit) may calculate a deterioration compensation gain value of a sub-pixel (SP) of the display panel based on a sensing voltage Vsen supplied from the data driver 140 and calculate a dimming weight value based on the calculated deterioration compensation gain value. Thereafter, the deterioration compensation unit 150 may modulate input image data (Idata) of each sub-pixel (SP) of a current frame with the calculated deterioration compensation gain value and the dimming weight value, and supply modulated image data (Mdata) to the timing controller 120.

The timing controller 120 may receive not only the image data modulated by the deterioration compensation unit 150 but also a driving signal and the like. The timing controller 120 may generate and output a gate timing control signal GDC for controlling the operation timing of the gate driver 130 and a data timing control signal DDC for controlling the operation timing of the data driver 140 based on the driving signal input from the image processing unit 110.

In addition, the timing controller 120 may control the operation timing of the gate driver 130 and the data driver 140 and obtain at least one sensing voltage Vsen from each sub-pixel SP and supply the sensing voltage Vsen to the deterioration compensation unit 150.

The gate driver 130 may output a scan signal to the display panel PAN in response to the gate timing control signal GDC supplied from the timing controller 120. The gate driver 130 may output scan signals through a plurality of gate lines GL1 to GLm. In this case, the gate driver 130 may be formed in the form of an integrated circuit (IC), but is not limited thereto. In particular, the gate driver 130 may be configured in a Gate In Panel (GIP) structure formed by directly stacking thin film transistors on a substrate inside the organic light emitting display device 100. A GIP area may include a plurality of circuits such as shift registers and level shifters.

The data driver 140 may output a data voltage to the display panel PAN in response to the data timing control signal DDC input from the timing controller 120. The data driver 140 may sample and latch a digital data signal DATA supplied from the timing controller 120 and convert the digital data signal DATA into an analog data voltage based on a gamma voltage.

The data driver 140 may output a data voltage through a plurality of data lines DL1 to DLn.

In addition, the data driver 140 may supply the sensing voltage Vsen input from the display panel PAN to the deterioration compensation unit 150 through a sensing voltage lead-out line.

In this case, the data driver 140 may be mounted on the upper surface of the display panel PAN in the form of an integrated circuit (IC) or directly formed on the display panel PAN, but is not limited thereto.

The power supply 180 may output a high potential driving voltage EVDD, a low potential driving voltage EVSS or the like that is less than the high potential driving voltage EVDD and supply the same to the display panel PAN. The high potential driving voltage EVDD and the low potential driving voltage EVSS may be supplied to the display panel PAN through a power line. In this case, the voltage output from the power supply 180 may be output to the data driver 140 or the gate driver 130 and used to drive the data driver 140 or the gate driver 130.

The display panel PAN may display images in response to a data voltage and a scan signal supplied from the data driver 140 and gate driver 130, which may be disposed in the non-display area NA, and power supplied from the power supply 180.

The display area AA of the display panel PAN may comprise of a plurality of sub-pixels SP to display an actual image. The sub-pixels SP may include a red sub-pixel, a green sub-pixel and a blue sub-pixel, or include a white (W) sub-pixel, a red (R) sub-pixel, a green (G) sub-pixel and a blue (B) sub-pixel. In this case, the W, R, G, and B sub-pixels SP may all be formed to have the same area, but may be formed to have different areas.

The memory 160 may store not only a look-up table for deterioration compensation gains, but also deterioration compensation timings for an organic light emitting element of a sub-pixel SP. In this case, the deterioration compensation timings of the organic light emitting element may be the number of drivings or driving time of an organic light emitting display panel.

In addition, the non-display area NA may include a bending area BA in which the display panel PAN is able to be bent or folded. The bending area BA refers to an area that is bent to fold and position areas that do not perform a display function, such as a signal pad (not shown), the gate driver 130, and the data driver 140, on the rear side of an display area AA. As shown in FIG. 1A, the bending area BA may be disposed between the display area AA and the data driver 140. In addition, the bending area BA may be disposed on at least one of the upper, lower, left, and right sides of the non-display area NA. Accordingly, an area occupied by the display area AA on the entire screen of the display device is maximized or increased, and the non-display area NA may be hidden behind the display area AA.

A signal link LK disposed in the bending area BA may connect the signal pad and signal lines disposed in the display area AA. The signal link LK may be arranged to reduce bending stress by extending in a direction crossing a bending direction to widen the area thereof.

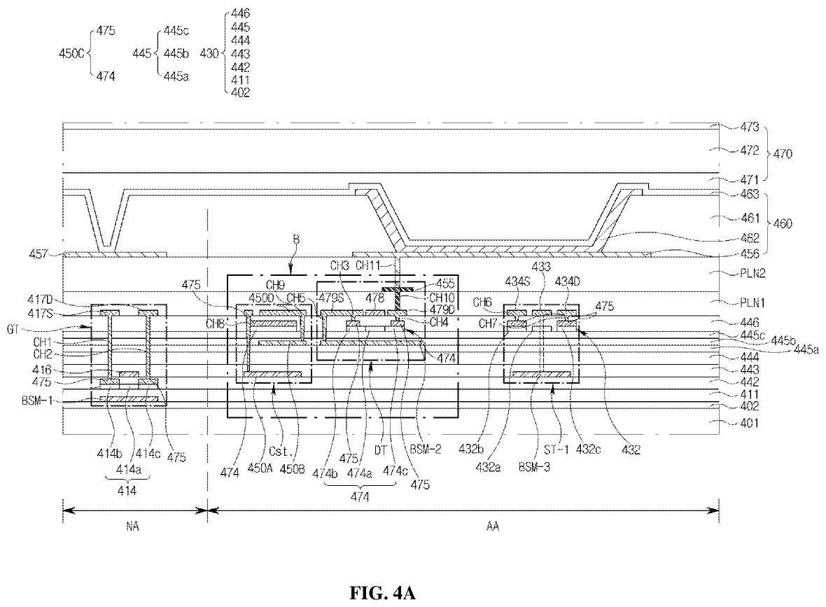

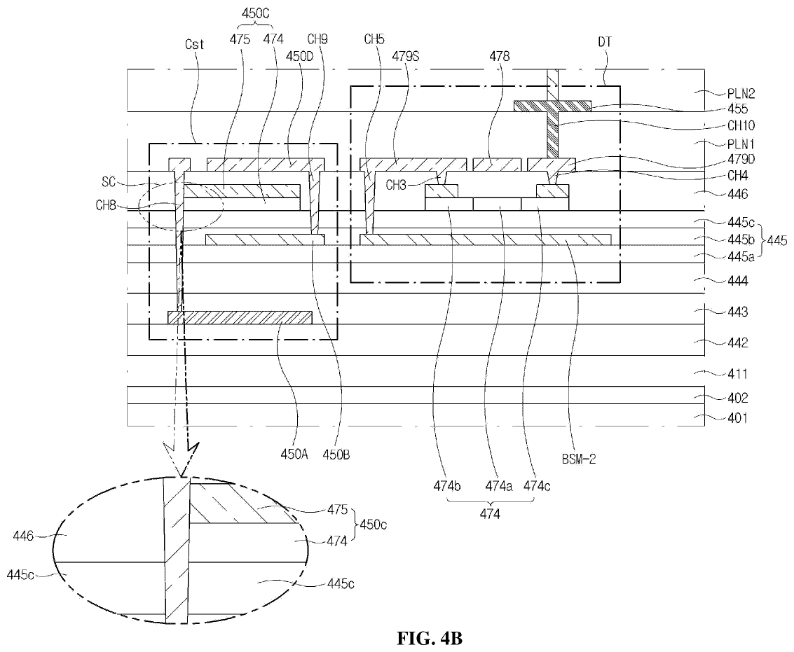

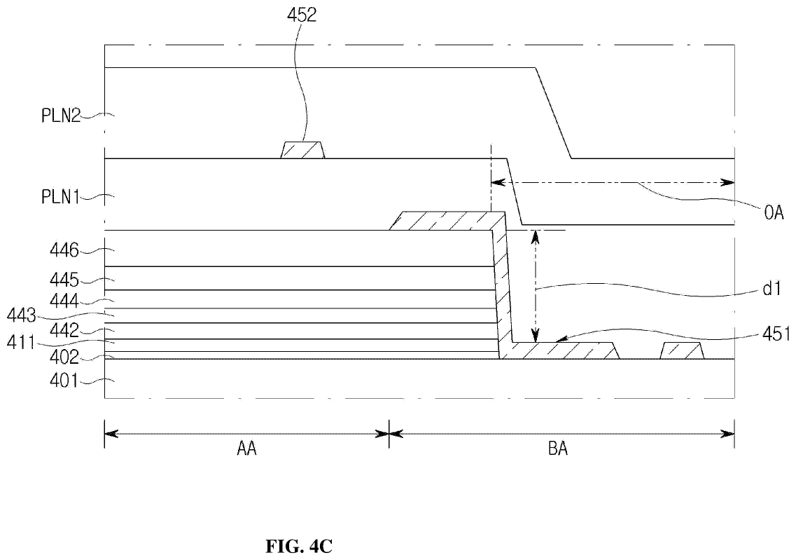

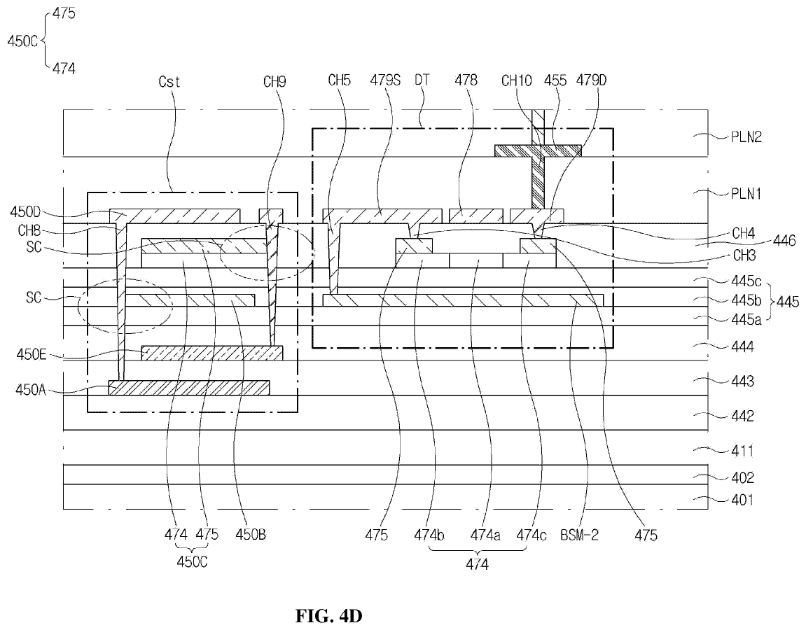

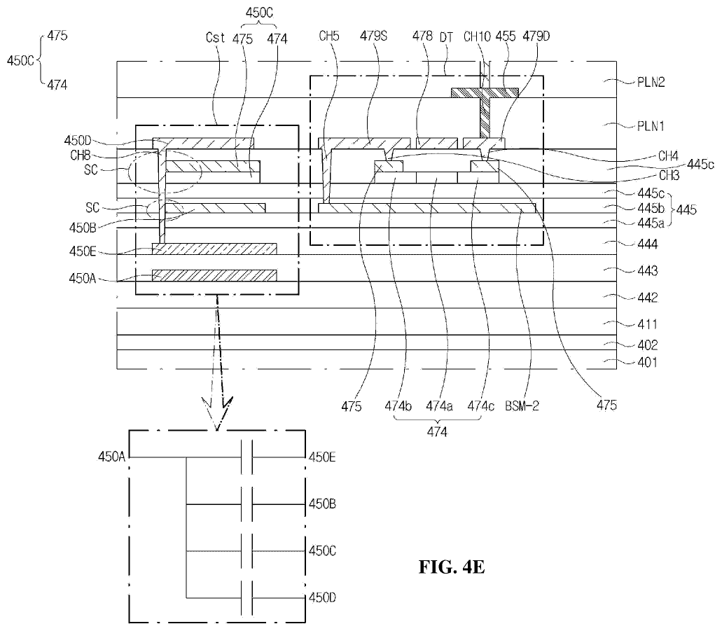

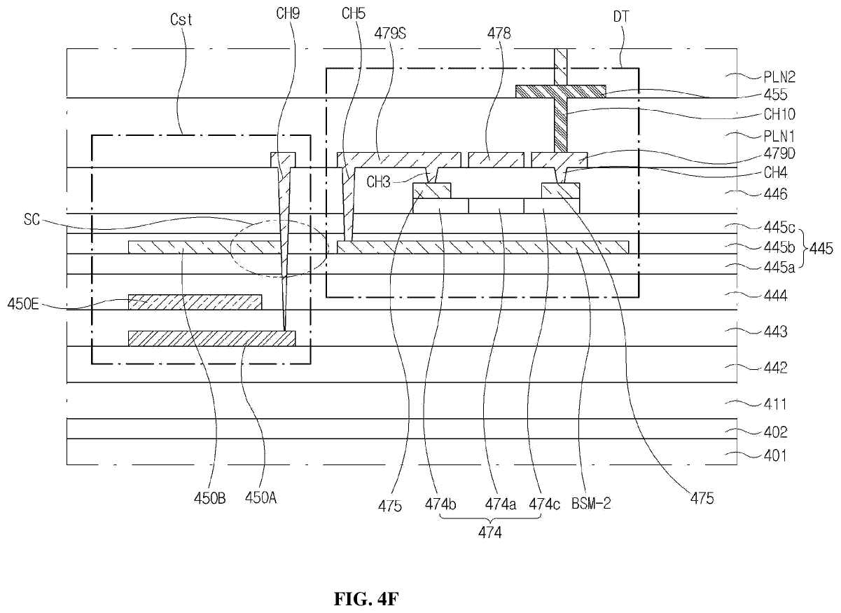

In addition, at least one open portion OA may be disposed in the bending area BA such that the bending area BA is easily bent, as shown in FIG. 4C. The open portion OA may be formed by removing a plurality of inorganic insulating layers 111 that cause cracks disposed in the bending area BA. Specifically, when the substrate 101 is bent, continuous bending stress may be applied to the inorganic insulating layers 111 disposed in the bending area BA. The inorganic insulating layers 111 may have lower elasticity than organic insulating materials, and cracks may easily occur in the inorganic insulating layer 111.

The cracks occurring in the inorganic insulating layer 111 may propagate to the display area AA along the inorganic insulating layers 111, causing line defects and device driving failures. Accordingly, at least one planarization layer PLN made of an organic insulating material having higher elasticity than the inorganic insulating layers 111 may be disposed in the bending area BA. The planarization layer PLN may relieve bending stress occurring when the substrate 101 is bent, thus reducing or preventing cracks from occurring. The open portion OA of the bending area BA is formed through the same mask process as at least one contact hole of a plurality of contact holes disposed in the display area AA, simplifying the structure and process thereof. The present disclosure provides a new structure that solves the problem of damage to a semiconductor pattern when the open portion OA of the bending area BA and at least one contact hole in the display area are formed. Details will be described below with reference to FIGS. 4A to 4C.

As shown in FIG. 2, one sub-pixel SP may be connected to a gate line GL1, a data line DL1, a sensing voltage read-out line SRL1, and a power line PL1. A driving method as well as the number of transistors and capacitors of the sub-pixel SP are determined according to the configuration of a circuit.

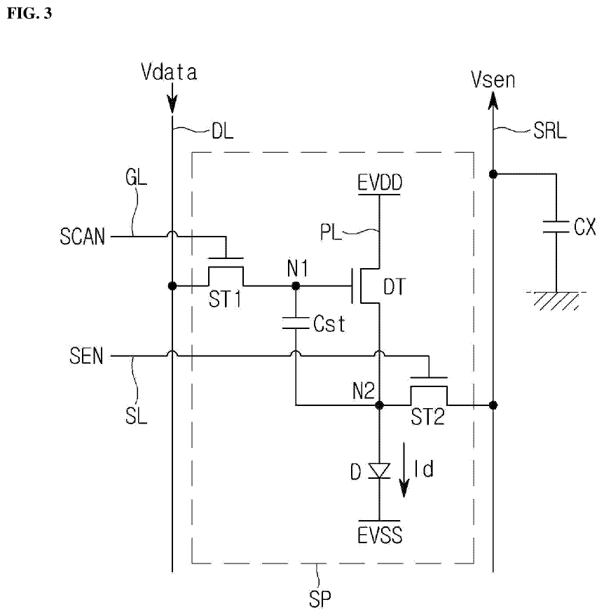

FIG. 3 is a circuit diagram illustrating a sub-pixel SP of an organic light emitting display device 100 according to the present disclosure.

Referring to FIG. 3, an organic light emitting display device 100 according to the present disclosure may include a gate line GL and a data line DL that cross each other to define a sub-pixel SP, a power line PL and a sensing line SL, and the sub-pixel SP may include a driving thin film transistor DT, an organic light emitting element D, a storage capacitor Cst, a first switching thin film transistor ST1 and a second switching thin film transistor ST2. However, the arrangement of the organic light emitting display device 100 is not limited to the above structure.

The organic light emitting element D may include an anode electrode connected to a second node N2, a cathode electrode connected to an input terminal of a low potential driving voltage EVSS, and an organic light emitting layer positioned between the anode electrode and the cathode electrode.

The driving thin film transistor DT may control a current Id flowing through the organic light emitting element D according to a gate-source voltage Vgs. The driving thin film transistor DT may include a gate electrode connected to a first node N1, a drain electrode connected to the power line PL to receive a high potential driving voltage EVDD, and a source electrode connected to the second node N2.

The storage capacitor Cst may be connected between the first node N1 and the second node N2.

The first switching thin film transistor ST1 may apply a data voltage Vdata charged in the data line DL to the first node N1 in response to a gate signal SCAN to turn on the driving thin film transistor DT when the display panel PAN is driven. In this case, the first switching thin film transistor ST1 may include a gate electrode connected to the gate line GL to receive a scan signal SCAN, a drain electrode connected to the data line DL to receive a data voltage Vdata, and a source electrode connected to the first node N1.

The second switching thin film transistor ST2 may store a source voltage of the second node N2 in the sensing capacitor Cx of the sensing voltage read-out line SRL by switching a current between the second node N2 and the sensing voltage read-out line SRL in response to the sensing signal SEN. The second switching thin film transistor ST2 may reset the source voltage of driving thin film transistor DT to an initialization voltage Vpre by switching a current between the second node N2 and the sensing voltage read-out line SRL in response to the sensing signal SEN when the display panel PAN is driven. In this case, the gate electrode of the second switching thin film transistor ST2 may be connected to a sensing line SL, the drain electrode may be connected to the second node N2, and the source electrode may be connected to the sensing voltage read-out line SRL.

Although the organic light emitting display device having a 3T1C structure including three thin film transistors and one storage capacitor has been described in the drawing as an example, the organic light emitting display device of the present disclosure is not limited to the above structure, and the present disclosure may be applied to various structures such as 4T1C, 5T1C, 6T1C, 7T1C, or 8T1C.

FIG. 4A is a cross-sectional view showing a first thin film transistor GT including a polycrystalline semiconductor pattern, a driving thin film transistor DT disposed in a sub-pixel of a display area AA and including an oxide semiconductor pattern and driving an organic light emitting element and a first switching thin film transistor ST-1 including an oxide semiconductor pattern and a storage capacitor Cst, the first thin film transistor GT is representative of thin film transistors disposed in a non-display area NA, in particular, a GIP area.

As shown in FIG. 4A, the driving thin film transistor DT and the first switching thin film transistor ST-1 may be disposed in a sub-pixel on a substrate 401. Although only the driving thin film transistor DT and one switching thin film transistor ST-1 are shown in FIG. 4A, this is only for convenience of description, and a plurality of switching thin film transistors may be disposed on the actual substrate 401.

In addition, a plurality of first thin film transistors GT constituting a gate driver may be disposed in the non-display area NA, particularly the GIP area, of the substrate 401. The first thin film transistor GT may be a polycrystalline thin film transistor using a polycrystalline semiconductor pattern as an active layer.

Although it is illustrated in FIG. 4A that the first thin film transistor GT is disposed in the non-display area NA, a polycrystalline thin film transistor as a switching thin film transistor having the same structure as the first thin film transistor GT may be disposed within a sub-pixel of the display area.

However, the first thin film transistor GT disposed in the non-display area NA and the first thin film transistor disposed in the display area AA are doped with different types of dopant, and are configured differently as an N-type thin film transistors and a P-type thin film transistor.

Meanwhile, the plurality of thin film transistors disposed in the gate driver may also be configured as a CMOS in which a polycrystalline thin film transistor and an oxide thin film transistor including an oxide semiconductor pattern as an active layer are paired with each other.

Hereinafter, the first thin film transistor using a polycrystalline semiconductor pattern disposed in the non-display area NA will be described as an example.

The substrate 401 may be composed of a multi-layer in which organic layers and inorganic layers are alternately stacked. For example, the substrate 401 may be formed by alternately stacking organic films such as polyimide and inorganic films such as silicon oxide (SiO2).

Lower buffer layers 402,411 may be formed on the substrate 401. The first lower buffer layer 402 is to prevent or at least reduce moisture from permeating from the outside, and may be configured by stacking a silicon oxide (SiO2) film or the like in multiple layers.

A first light blocking pattern BSM-1 may be formed on the first lower buffer layer 402. The light blocking pattern BSM can constitute a display signal line, or can constitute a portion of the storage capacitor disposed on a subpixel.

A second lower buffer layer 411 may be further formed on the first light blocking pattern BSM-1. The second lower buffer layer 411 may be made of the same material as the first lower buffer layer 402.

The first thin film transistor GT may include a first polycrystalline semiconductor pattern 414 disposed on the second lower buffer layer 411, a first gate insulating layer 442 insulating the first polycrystalline semiconductor pattern 414, a first gate electrode 416 disposed on the first gate insulating layer 442 and overlapping the first polycrystalline semiconductor pattern 414, a plurality of insulating layers formed on the first gate electrode 416, and a first source electrode 417S and a first drain electrode 417D disposed on the plurality of insulating layers.

The first thin film transistor GT may include a first light blocking pattern BSM-1 under the first polycrystalline semiconductor pattern 414. The first light blocking pattern BSM-1 may protect the first polycrystalline semiconductor pattern 414 from light entering from the outside of the display device. The first light blocking pattern BSM-1 may be formed selectively rather than as an essential component.

The first light blocking pattern BSM-1 may be formed as a metal pattern on the first lower buffer layer 402. The material of the first light blocking pattern BSM-1 is not limited to a metal thin film.

The first light blocking pattern BSM-1 may be formed under the first polycrystalline semiconductor pattern 414 and is larger than the first polycrystalline semiconductor pattern 414 to completely block external light entering the first polycrystalline semiconductor pattern 414 according to one embodiment. Therefore, the first light blocking pattern BSM-1 may completely overlap the first polycrystalline semiconductor pattern 414.

The first polycrystalline semiconductor pattern 414 may include a first channel region 414a lightly doped with an intrinsic semiconductor or dopant, and a first source region 414b and a first drain region 414c highly doped with dopant ions to have conductivity.

The first source region 414b and the first drain region 414c may be doped with N-type or P-type dopant. According to a type of dopant to be doped, the first thin film transistor GT may be an N-type thin film transistor or a P-type thin film transistor.

However, a process of performing doping with dopant is generally required to form the first source region 414b and the first drain region 414c, and in some cases, a mask may be required.

This process makes the process complicated and increases manufacturing costs.

Therefore, in the present embodiment, the first source region 414b and the first drain region 414c are not made conductive by performing no process of doping the polycrystalline semiconductor pattern with dopant ions and a conductive pattern 475 are formed above the first source region 414b and the first drain region 414c.

The conductive pattern 475 may be a conductive metal material. The conductive pattern 475 is not limited to a metal material, and may be a conductive material that is more resistant to etching than an inorganic insulating layer.

The conductive pattern 475 may be disposed while directly contacting the upper surfaces of the first source region 414b and the first drain region 414c.

The conductive pattern 475 may completely overlap the first source region 414b and the first drain region 414c, but may partially overlap the first source region 414b and the first drain region 414c. However, the first source electrode 417S and the first drain electrode 417D physically contacting the first source region 414b and the first drain region 414c may be preferably disposed to directly contact the conductive pattern 475.

The first polycrystalline semiconductor pattern 414 and the conductive pattern 475 may be simultaneously formed through a single mask process using a halftone mask.

The conductive pattern 475 may be formed of a material that is resistant to etching during a process of etching the inorganic insulating layers when a contact hole passing through the plurality of inorganic insulating layers deposited on the conductive pattern 475 is formed according to one embodiment. Therefore, the conductive pattern 475 may be an etch-resistant metal pattern that is resistant to a dry etching process in the dry etching process of etching an inorganic insulating layer.

The first gate insulating layer 442 may be deposited on the first polycrystalline semiconductor pattern 414. The first polycrystalline semiconductor pattern 414 may be insulated by the first gate insulating layer 442. The first gate insulating layer 442 may be formed by depositing an inorganic insulating layer such as silicon oxide (SiO2) on the entire surface of the substrate 401 on which the first polycrystalline semiconductor pattern 414 is formed. The first gate insulating layer 442 may insulate the first polycrystalline semiconductor pattern 414 from the outside.

The first gate electrode 416 overlapping the first channel region 414a of the first polycrystalline semiconductor pattern 414 may be formed on the first gate insulating layer 442.

The first gate electrode 416 may be made of a metal material. For example, the first gate electrode 416 may be a single layer or multiple layers made of any one of molybdenum (Mo), aluminum (Al), chromium (Cr), gold (Au), titanium (Ti), nickel (Ni), neodymium (Nd), or copper (Cu) or an alloy thereof, but embodiments of the present disclosure is not limited thereto.

A plurality of insulating layers may be formed between the first gate electrode 416 and the first source electrode 417S and the first drain electrode 417D.

Referring to FIG. 4A, the plurality of insulating layers may include a first interlayer insulating layer 443 contacting the upper surface of the first gate electrode 416, a second interlayer insulating layer 444 sequentially stacked thereon, an upper buffer layer 445, and a second gate insulating layer 446. In some cases, the second interlayer insulating layer 444 may be omitted. In addition, a third interlayer insulating layer (not shown) may be further formed on the second gate insulating layer 446.

The first source electrode 417S and the first drain electrode 417D may be disposed on the second gate insulating layer 446. The first source electrode 417S and the first drain electrode 417D may be connected to the first source region 414b and the first drain region 414c via the first contact hole CH1 and the second contact hole CH2, which pass through the first gate insulating layer 442, the first interlayer insulating layer 443, the second interlayer insulating layer 444, the upper buffer layer 445 and the second gate insulating layer 446. Specifically, in the present embodiment, the first source electrode 417S and the first drain electrode 417D may be connected to the conductive patterns 475 formed on the upper surfaces of the first source region 414b and the first drain region 414c, respectively.

In the present embodiment, the conductive pattern 475 may prevent or at least reduce the first polycrystalline semiconductor pattern 414 from being etched by an etching gas while the first contact hole CH1 and the second contact hole CH2 are formed to pass through the first gate insulating layer 442 made of an inorganic insulating film, the first interlayer insulating layer 443, the second interlayer insulating layer 444, the upper buffer layer 445, and the second gate insulating layer 446. The conductive pattern 475 has excellent etching resistance against an etching gas that etches an inorganic insulating layer to protect the first polycrystalline semiconductor pattern 414 even when the conductive pattern 475 is exposed to the etching gas for a long time.

Meanwhile, referring to FIG. 4A, the driving thin film transistor DT, the first switching thin film transistor ST-1, and the storage capacitor Cst are disposed in a sub-pixel of the display area AA.

The driving thin film transistor DT and the first switching thin film transistor ST-1 may use an oxide semiconductor pattern as an active layer.

The oxide semiconductors may be made of an oxide of a metal such as zinc (Zn), indium (In), gallium (Ga), tin (Sn), and titanium (Ti) or a combination of a metal such as zinc (Zn), indium (In), gallium (Ga), tin (Sn), or titanium (Ti). Specifically, the oxide semiconductor may include zinc one or more of oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO) and the like.

In the related art, a polycrystalline semiconductor pattern, which is advantageous for high-speed operation, was used as an active layer for a driving thin film transistor. However, a leakage current may occur in the driving thin film transistor including a polycrystalline semiconductor pattern in an off state, resulting in power consumption. In particular, power consumption in an off state becomes more problematic when the display device is operated at a low speed such as a still image displaying a document screen. Therefore, in one embodiment of the present disclosure, a driving thin film transistor using an oxide semiconductor pattern, which is advantageous for reducing or preventing a leakage current from occurring, as an active layer is proposed.

However, the thin film transistor using an oxide semiconductor pattern as an active layer is likely to have defects in a low grayscale region where precise current control is required because a variation value in current for a unit variation value in voltage is large due to the nature of the material of the oxide semiconductor. Therefore, embodiments of the present disclosure may provide a driving thin film transistor in which the change value of current in the active layer is relatively insensitive with respect to the change value of voltage applied to the gate electrode.

However, the thin film transistor using an oxide semiconductor pattern as an active layer is likely to have defects in a low grayscale region where precise current control is required because a variation value in current for a unit variation value in voltage is large due to the nature of the material of the oxide semiconductor. Accordingly, a first embodiment of the present disclosure provides a driving thin film transistor in which the change value of current in the active layer is relatively insensitive with respect to the change value of voltage applied to the gate electrode.

Referring to FIG. 4A, a driving thin film transistor DT may include a first oxide semiconductor pattern 474 positioned on the upper buffer layer 445, a second gate insulating layer 446 covering the first oxide semiconductor pattern 474, a second gate electrode 478 formed on the second gate insulating layer 446 and overlapping the first oxide semiconductor pattern 474, and a second source electrode 479S and a second drain electrode 479D disposed in the same layer as the second gate electrode 478.

In addition, the first oxide semiconductor pattern 474 as an active layer may include a second channel region 474a through which charges move, and a second source region 474b and a second drain region 474c which are adjacent to the second channel region 474a with the second channel region 474a interposed therebetween. In addition, in the first oxide semiconductor pattern 474, the conductive patterns 475 are disposed on the second source region 474b and the second drain region 474c, respectively. The conductive patterns 475 make the second source region 474b and the second drain region 474c conductive, respectively.

The conductive pattern 475 may be a conductive metal pattern. For example, the conductive pattern 475 may be a “transparent/opaque” metal layer such as Mo, Ti, MoTi, IZO, ITO, Cu, or Al. In particular, since the conductive patterns 475 come into surface contact with the second source region 474b and the second drain region 474c configured as oxide semiconductor patterns, the conductive patterns 475 are made of a material capable of ohmic contact to reduce a surface contact resistance according to one embodiment. In addition, when a third contact hole CH3 connecting the second source electrode 479S and the second source region 474b is formed in the second gate insulating layer 446, the conductive pattern 475 may be made of a material having a higher etching resistance compared to the second gate insulating layer 446 which is an inorganic insulating layer. That is, when the third contact hole CH3 is formed by etching the second gate insulating layer 446, which is an inorganic insulating layer, the conductive pattern 475 disposed on the second source region 474b is resistant to etching to protect the second source region 474b from an etching gas.

The second channel region 474a may be made of an intrinsic oxide semiconductor not doped with dopant. In addition, since the second source region 474b and the second drain region 474c already have the conductive pattern 475 on the second source region 474b and the second drain region 474c, the second source region 474b and the second drain region 474c may be made of an intrinsic oxide semiconductor.

Meanwhile, a second light blocking pattern BSM-2 may be formed under the first oxide semiconductor pattern 474. The second light blocking pattern BSM-2 may reduce or prevent external light from being radiated to the first oxide semiconductor pattern 474 to reduce or prevent the first oxide semiconductor pattern 474 from malfunctioning.

The second light blocking pattern BSM-2 may be a metal layer including a titanium (Ti) material capable of trapping hydrogen atoms. For example, the second light blocking pattern BSM-2 may be a single layer of titanium, a double layer of molybdenum (Mo) and titanium (Ti), or an alloy of molybdenum (Mo) and titanium (Ti). However, the present disclosure is not limited thereto, and another metal layer including titanium (Ti) is also possible.

Titanium (Ti) may trap hydrogen atoms diffusing into the upper buffer layer 445 to prevent the hydrogen atoms from reaching the first oxide semiconductor pattern 474.

The second light blocking pattern BSM-2 is formed vertically under the first oxide semiconductor pattern 474 so as to overlap the first oxide semiconductor pattern 474 according to one embodiment. Also, the second light blocking pattern BSM-2 may be formed larger than the first oxide semiconductor pattern 474 so as to completely overlap the first oxide semiconductor pattern 474.

Meanwhile, the second source electrode 479S of the driving thin film transistor DT may be electrically connected to the second light blocking pattern BSM-2. When the second light blocking pattern BSM-2 is electrically connected to the second source electrode 479S, the following additional technical effects may be obtained.

As the second source region 474b and the second drain region 474c of the first oxide semiconductor pattern 474 include the conductive patterns 475, respectively, a parasitic capacitance Cact may occur in the first oxide semiconductor pattern 474, a parasitic capacitance Cgi may occur between the second gate electrode 478 and the first oxide semiconductor pattern 474, and a parasitic capacitance Cbuf may occur between the second light blocking pattern BSM-2 electrically connected to the second source electrode 479S and the first oxide semiconductor pattern 474.

Since the first oxide semiconductor pattern 474 and the second light blocking pattern BSM-2 are electrically connected by the second source electrode 479S, the parasitic capacitance Cact and the parasitic capacitance Cbuf may be connected in parallel, and the parasitic capacitance Cact and the parasitic capacitance Cgi may be connected in series Also, when a gate voltage Vgat is applied to the second gate electrode 478, an effective voltage Veff (ΔV) practically applied to the first oxide semiconductor pattern 474 is obtained by formula 1 below.

$$ΔV eff = \frac{Cgi}{( Cgi + Gbuf + Cact )} \times ΔV gat$$

Therefore, since the effective voltage Veff (ΔV) applied to the second channel region 474a is in inverse proportion to the parasitic capacitance Cbuf, the effective voltage applied to the first oxide semiconductor pattern 474 may be controlled by adjusting the parasitic capacitance Cbuf.

That is, when the parasitic capacitance Cbuf is increased by disposing the second light blocking pattern BSM-2 close to the first oxide semiconductor pattern 474, an actual current flowing through the first oxide semiconductor pattern 474 may be reduced. Accordingly, the upper buffer layer 445 interposed between the second light blocking pattern BSM-2 and the first oxide semiconductor pattern 474 may be thinner than the second gate insulating layer 446 interposed between the first oxide semiconductor pattern 474 and the second gate electrode 478. In addition, a dielectric constant of the upper buffer layer 445 interposed between the second light blocking pattern BSM-2 and the first oxide semiconductor pattern 474 may be greater than a dielectric constant of the second gate insulating layer 446 interposed between the first oxide semiconductor pattern 474 and the second gate electrode 478.

Reducing the effective current flowing through the first oxide semiconductor pattern 474 may mean increasing an S-factor and mean that a control range of the driving thin film transistor DT capable of being controlled through a voltage Vgat actually applied to the second gate electrode 478 is widened.

That is, when the second source electrode 479S of the driving thin film transistor DT and the second light-shielding pattern BSM-2 are electrically connected, it is possible to control light emitting elements precisely even in low grayscales, thus solving screen stains frequently occurring in low grayscales.

For reference, the S-factor is commonly referred to as a “sub-threshold slope”, and may refer to a reciprocal value of the amount of change in current according to the amount of change in gate voltage in the on/off transition region of a thin film transistor.

Since a small S-factor means that the slope of the characteristic graph (I-V) of a drain current with respect to a gate voltage is large, a thin film transistor is turned on even by a small voltage, and therefore the switching characteristics of the thin film transistor are improved. On the other hand, a threshold voltage is reached for a short time period to make sufficient grayscale expression difficult.

Since a large S-factor means that the slope of the characteristic graph (I-V) of the drain current with respect to the gate voltage is small, the on/off reaction speed of the thin film transistor is lowered, and thus the switching characteristics of the thin film transistor are lowered, but the threshold voltage is reached for a relatively long time period to make sufficient grayscale expression possible.

In particular, the second light blocking pattern BMS-2 may be disposed close to the first oxide semiconductor pattern 474 while being inserted into the upper buffer layer 445. However, it is exemplified in the first embodiment that a plurality of sub-upper buffer layers are used. That is, the upper buffer layer 445 may have a structure in which a first sub-upper buffer layer 445a, a second sub-upper buffer layer 445b, and a third sub-upper buffer layer 445c are sequentially stacked. The second light blocking pattern BSM-2 may be formed on the first sub-upper buffer layer 445a. Also, the second sub-upper buffer layer 445b may completely cover the second light blocking pattern BSM-2. Further, the third sub-upper buffer layer 445c may be formed on the second sub-upper buffer layer 445b.

The first sub-upper buffer layer 445a and the third sub-upper buffer layer 445c may be made of silicon oxide (SiO2).

The first sub-upper buffer layer 445a and the third sub-upper buffer layer 445c are made of hydrogen-free silicon oxide (SiO2), thereby preventing or at least reducing hydrogen atoms from penetrating into the oxide semiconductor pattern during a heat treatment process. When hydrogen atoms penetrate the oxide semiconductor pattern, the reliability of the thin film transistor may be damaged.

On the other hand, the second sub-upper buffer layer 445b may be made of silicon nitride (SiNx) having an excellent ability to trap hydrogen atoms. The second sub-upper buffer layer 445b may be partially formed on the first sub-upper buffer layer 445a to cover both the upper and side surfaces of the second light blocking pattern BSM-2 so as to completely seal the second light blocking pattern BSM-2, and the second sub-upper buffer layer 445b may be formed on the entire surface of the first sub-upper buffer layer 445a in which the second light blocking pattern BSM-2 is formed.

Silicon nitride (SiNx) has a superior ability to trap hydrogen atoms compared to silicon oxide (SiO2). When hydrogen atoms penetrate into the oxide semiconductor pattern, the oxide semiconductor may have different threshold voltages or a varying conductivity of the channel depending on where the oxide semiconductor is formed. That is, reliability is damaged. In particular, in the case of a driving thin film transistor, it is important to secure reliability as the driving thin film transistor directly contributes to the operation of a light emitting element.

Therefore, in the embodiment of the present disclosure, the second sub-upper buffer layer 445b covering the second light blocking pattern BMS-2 is partially or entirely formed on the first sub-upper buffer layer 445a, thus reducing or preventing reliability of the driving thin film transistor DT from being damaged due to the hydrogen atoms.

In addition, in the embodiment of the present disclosure, the second light blocking pattern BSM-2 may be a metal layer including a titanium (Ti) material capable of collecting hydrogen atoms. For example, the second light blocking pattern BSM-2 may be a single layer of titanium, a double layer of molybdenum (Mo) and titanium (Ti), or an alloy of molybdenum (Mo) and titanium (Ti). However, the present disclosure is not limited thereto, and another metal layer including titanium (Ti) is also possible.

Titanium (Ti) may trap hydrogen atoms diffusing into the upper buffer layer 445 to reduce or prevent the hydrogen atoms from reaching the first oxide semiconductor pattern 474. Therefore, in the driving thin film transistor DT according to the embodiment of the present disclosure, the second light blocking pattern BSM-2 is formed as a metal layer such as titanium capable of trapping hydrogen atoms, and the second light blocking pattern BSM-2 is covered by a silicon nitride (SiNx) layer capable of trapping hydrogen atoms, thus solving a problem in which reliability of the oxide semiconductor pattern is damaged due to hydrogen atoms.

Since the second sub-upper buffer layer 445b is made of a material different from that of the first sub-upper buffer layer 445a, that is, a silicon nitride (SiNx) film, film lifting may occur when the second sub-upper buffer layer 445b is deposited on the entire surface of the display area. In order to solve or avoid for the above problem, the second sub-upper buffer layer 445b may be selectively formed only on a necessary portion, that is, only on a location where the second light blocking pattern BSM-2 is formed.

The second light blocking pattern BSM-2 is formed vertically under the first oxide semiconductor pattern 474 so as to overlap the first oxide semiconductor pattern 474 in view of its function according to one embodiment. Also, the second light blocking pattern BSM-2 may be formed larger than the first oxide semiconductor pattern 474 so as to completely overlap the first oxide semiconductor pattern 474.

In addition, in the driving thin film transistor DT, the second gate electrode 478 may be disposed on the first oxide semiconductor pattern 474. The second gate electrode 478 may overlap the second channel region 474a. The second gate insulating layer 446 may be interposed between the second gate electrode 478 and the first oxide semiconductor pattern 474.

The second source electrode 479S and the second drain electrode 479D may be formed in the same layer as the second gate electrode 478. That is, the second gate electrode 478, the second source electrode 479S, and the second drain electrode 479D may be simultaneously formed on the second gate insulating layer 446.

According to an embodiment of the present disclosure, since the second source region 474b and the second drain region 474c are not subjected to a process for conductivity such as a process of doping the second source region 474b and the second drain region 474c with dopant ions or a process of performing ion bombardment, the second source electrode 479S and the second drain electrode 479D may be formed on the second gate insulating layer 446 to overlap the second source region 474b and the second drain region 474c. That is, it is possible to simultaneously form the second gate electrode 478, the second source electrode 479S, and the second drain electrode 479D. That is, the number of masks may be reduced.

The second source electrode 479S may be connected to a conductive pattern 475 disposed on the second source region 474b through the third contact hole CH3 passing through the second gate insulating layer 446, and the second drain electrode 479D may be connected to the conductive pattern 475 disposed on the second drain region 474c through the fourth contact hole CH4.

On the other hand, the second source electrode 474S may be electrically connected to the second light blocking pattern BSM-2 through the fifth contact hole CH5.

The first switching thin film transistor ST-1 may include a second oxide semiconductor pattern 432, a third gate electrode 433, a third source electrode 434S, and a third drain electrode 434D.

The second oxide semiconductor pattern 432 may include a third channel region 432a, and a third source region 432b and a third drain region 432c adjacent to the third channel region 432a with the third channel region interposed therebetween. In particular, the conductive pattern 475 may be disposed on the third source region 432b and the third drain region 432c like the driving thin film transistor DT.

The third gate electrode 433 may be disposed on the second oxide semiconductor pattern 432 with the second gate insulating layer 446 interposed therebetween.

The third source electrode 434S and the third drain electrode 434D may be disposed in the same layer as the third gate electrode 433. That is, the third source electrode 434S, the third drain electrode 434D, and the third gate electrode 433 may be simultaneously made of the same material on the second gate insulating layer 446.

Also, a third light blocking pattern BSM-3 may be disposed under the second oxide semiconductor pattern 432.

The third light blocking pattern BSM-3 may be disposed under the second oxide semiconductor pattern 432 to overlap the second oxide semiconductor pattern 432 in order to protect the second oxide semiconductor pattern 432 from light entering from the outside.

The third light blocking pattern BSM-3 may be formed over the first gate insulating layer 442 or the first interlayer insulating layer 443.

The third gate electrode 433 and the third light blocking pattern BSM-3 may be electrically connected to each other to form a dual gate.

Meanwhile, referring to FIG. 4A, a sub-pixel may further include a storage capacitor Cst.

The storage capacitor Cst may store a data voltage applied through a data line for a certain period of time and provide the data voltage to an organic light emitting element.

Today, as display devices increase in resolution, the size of a unit sub-pixel is reduced and the area occupied by a storage capacitor in a sub-pixel is also reduced. Various types of storage capacitors capable of obtaining larger capacitance values within a limited size will be described in the present embodiment.

In an embodiment of the present disclosure referring to FIG. 4A, the storage capacitor Cst may include a metal pattern disposed in the same layer as the conductive pattern 475 positioned in the driving thin film transistor DT as one electrode. FIG. 4B is an enlarged cross-sectional view of area B of FIG. 4A according to one embodiment of the present disclosure.

Referring to FIGS. 4A and 4B, the storage capacitor Cst may include a first electrode 450A of the storage capacitor disposed in the same layer as the first gate electrode 416, a second electrode 450B of the storage capacitor disposed in the same layer as the second light blocking pattern BSM-2, a third electrode 450C of the storage capacitor including a metal pattern disposed in the same layer as the conductive pattern 475, and a fourth electrode 450D of the storage capacitor disposed in the same layer as the second gate electrode.

In the present embodiment, in order to reduce mask processes, the third electrode 450C of the storage capacitor may be a structure in which a metal pattern disposed in the same layer as the conductive pattern 475 and an oxide semiconductor pattern formed on a lower surface of the metal pattern are stacked. That is, the third electrode 450C of the storage capacitor may be formed simultaneously with the first oxide semiconductor pattern 474 and the conductive pattern 475 stacked on first oxide semiconductor pattern 474 by sequentially depositing an oxide semiconductor pattern and a conductive layer on the upper buffer layer 445, and then performing patterning using one half-tone mask. Accordingly, the third electrode 450C of the storage capacitor may have a structure in which an oxide semiconductor pattern and a metal pattern constituting the conductive pattern 475 are stacked.

However, the third electrode 450C of the storage capacitor is not limited to the stacked structure and may be configured as a single layer of a metal pattern made of the same material as the conductive pattern 475.

The first electrode 450A of the storage capacitor may be electrically connected to the third electrode 450C of the storage capacitor through an eighth contact hole CH8. Also, the second electrode 450B of the storage capacitor may be electrically connected to the fourth electrode of the storage capacitor through a ninth contact hole CH9. By arranging the electrodes of the storage capacitor as described above, sub-storage capacitances formed between the electrodes adjacent to each other may be connected in parallel with each other. As a result, the total capacitance of the storage capacitor Cst may increase.

In addition, in the storage capacitor Cst according to the present embodiment, mask processes may be reduced by simultaneously forming the first contact hole CH1 to the ninth contact hole CH9 using one mask. Here, the mask process refers to a series of photolithography processes of performing exposure, etching, development, and cleaning using one mask.

In the present embodiment, the first contact hole CH1, the third contact hole CH3, the eighth contact hole CH8, and the ninth contact hole CH9 may have different depths, but metal patterns disposed at the lower ends of the contact holes may protect the lower ends of the contact holes during the process of forming the contact holes because the metal patterns block an etching gas. Accordingly, the contact holes having different depths can be formed through a single mask process.

Therefore, referring to FIG. 4B, the third electrode 450C of the storage capacitor may be in side contact with the eighth contact hole CH8 in an side contact area SC such that the first contact hole CH1 to the ninth contact hole CH9 are formed through one mask process.

When the eighth contact hole CH8 is located on the upper end of the third electrode 450C of the storage capacitor, the metal pattern may block the etching gas, so that the eighth contact hole CH8 cannot connect the first electrode 450A of the storage capacitor and the third electrode 450C of the storage capacitor with each other. However, when the third electrode 450C of the storage capacitor is in side contact with the eighth contact hole CH8, the first electrode 450A of the storage capacitor and the third electrode 450C of the storage capacitor may be connected to each other only through the eighth contact hole CH8. The eighth contact hole CH8 may expose an upper end of the first electrode 450A of the storage capacitor.

After the second gate insulating layer 446 covering the first oxide semiconductor pattern 474 is deposited, the first contact hole CH1 to ninth contact hole CH9 are formed through one mask process.

When a conductive material is deposited on the second gate insulating layer 446, the contact holes may be filled with a conductive material and in this process, electrodes of the storage capacitor may be connected to each other by the conductive material. Then, when the conductive material is patterned, the second gate electrode 478, the second source electrode 479S, the second drain electrode 479D, and the fourth electrode 450D of the storage capacitor may be formed. The conductive material may be such as copper (Cu), aluminum (Al), molybdenum (Mo), nickel (Ni), titanium (Ti), chrome (Cr), or an alloy thereof, but is not limited thereto.

In addition, referring to FIG. 4C, when the first contact hole CH1 to the ninth contact hole CH9 are formed, an inorganic insulating layer deposited on the bending area BA of the non-display area NA may be removed at the same time to form an open portion OA. As a result, a thin film transistor array substrate may be fabricated while reducing the number of masks. That is, in the present embodiment, since the first contact hole CH1 to the ninth contact hole CH9 include metal patterns at their lower ends, the first contact hole CH1 to the ninth contact hole CH9 may be formed in one mask process and at the same time, a plurality of inorganic insulating layers deposited on the bending area BA may be etched to remove the inorganic insulating layers from the bending area BA at once.

Meanwhile, another configuration of the storage capacitor Cst of the present disclosure will be described with reference to FIG. 4D.

Referring to FIG. 4D, the storage capacitor Cst according to the present embodiment may further include a fifth electrode 450E of the storage capacitor between the first electrode 450A and the second electrode 450B of the storage capacitor.

The fifth electrode 450E of the storage capacitor may serve as one electrode of the storage capacitor Cst and increase a degree of freedom in wiring design. That is, by adding the fifth electrode 450E of the storage capacitor, one electrode of the storage capacitor may be configured within a sub-pixel of the display area, and various link lines and connection lines disposed in the non-display area may be configured.

The fifth electrode 450E of the storage capacitor may be disposed on the first interlayer insulating layer 443 covering the first polycrystalline semiconductor pattern 414. The fifth electrode 450E of the storage capacitor may be disposed to overlap the first electrode 450A of the storage capacitor and the second electrode 450B of the storage capacitor.

Also, the first electrode 450A of the storage capacitor, the second electrode 450B of the storage capacitor, and the fourth electrode 450D of the storage capacitor may be electrically connected to each other.

Also, the third electrode 450C of the storage capacitor and the fifth electrode 450E of the storage capacitor may be electrically connected to each other. With the above-described configuration, each of the electrodes of the storage capacitor may form a sub-storage capacitance with an electrode of the storage capacitor adjacent thereto, and the sub-storage capacitances may be connected in parallel with each other, thereby increasing the total capacitance of the storage capacitor.

Also, in the storage capacitor Cst shown in FIG. 4D, the second electrode 450B of the storage capacitor may be in side contact with the eighth contact hole CH8 in the side contact area SC, and the third electrode 450C of the storage capacitor may be in side contact with the ninth contact hole CH9 in the side contact area SC such that the first contact hole CH1 to the ninth contact hole CH9 are formed through one mask process.

The first electrode 450A of the storage capacitor to the fifth electrode 450E of the storage capacitor may be connected in different methods to form the storage capacitor Cst.

Hereinafter, another configuration of the storage capacitor Cst disclosed in FIG. 4E will be described.

In the storage capacitor Cst illustrated in FIG. 4E, the second electrode 450B of the storage capacitor to the fifth electrode 450E of the storage capacitor may be connected to each other through the eighth contact hole CH8. Also, the first electrode 450A of the storage capacitor may individually correspond to the second electrode 450B of the storage capacitor to the fifth electrode 450E of the storage capacitor to form sub-storage capacitances. As a result, the sum of sub-storage capacitances may increase.

In order to connect the second electrode 450B of the storage capacitor to the fifth electrode 450E of the storage capacitor with each other through one contact hole, the second electrode 450B of the storage capacitor and the third electrode 450C of the storage capacitor may be in side contact with the eighth contact hole CH8.

As a result, the second electrode 450B of the storage capacitor to the fifth electrode 450E of the storage capacitor may be electrically connected to each other through the eighth contact hole CH8 passing through the second interlayer insulating layer 444, the upper buffer layer 445, and the second gate insulating layer 446 disposed on the fifth electrode 450E of the storage capacitor.

Meanwhile, referring to FIG. 4F, the storage capacitor Cst of the present disclosure may be configured without including the third electrode 450C of the storage capacitor. FIG. 4F illustrates an example.

Referring to FIG. 4F, the storage capacitor Cst may include a first electrode 450A of the storage capacitor disposed in the same layer as the first gate electrode 416, a second electrode 450B of the storage capacitor disposed in the same layer as the second light blocking pattern BSM-2, and a fifth electrode 450E of the storage capacitor disposed between the two electrodes. Sub-capacitances may be formed between the electrodes of the storage capacitor adjacent to each other and may be connected in parallel to each other by electrically connecting the first electrode 450A of the storage capacitor and the second electrode 450B of the storage capacitor to each other.

The storage capacitor Cst shown in FIG. 4F may also have an electrode of the storage capacitor which is in side contact with the ninth contact hole CH9 such that the electrodes of the storage capacitor are formed through one mask process when the electrodes of the storage capacitor are connected to each other. In the storage capacitor Cst shown in FIG. 4F, the second electrode 450B of the storage capacitor may be in side contact with the ninth contact hole CH9.

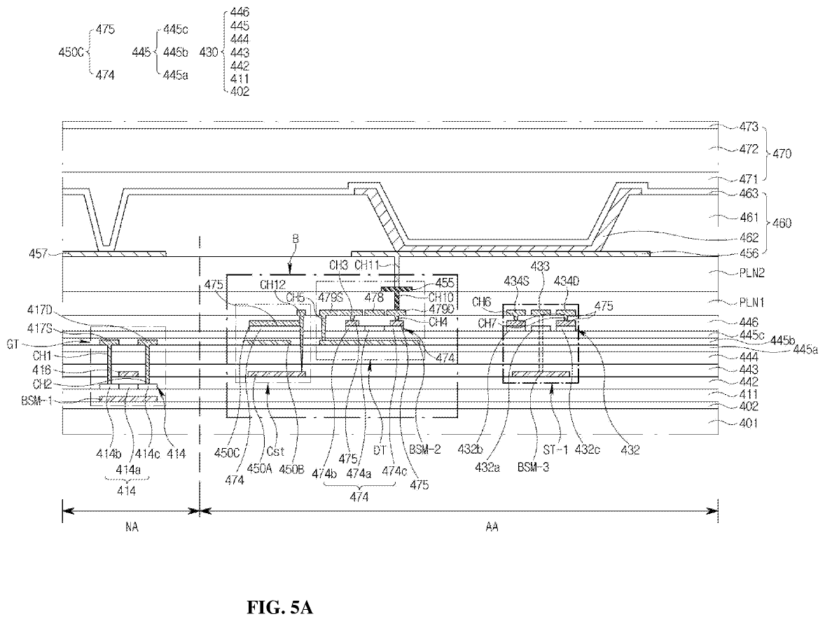

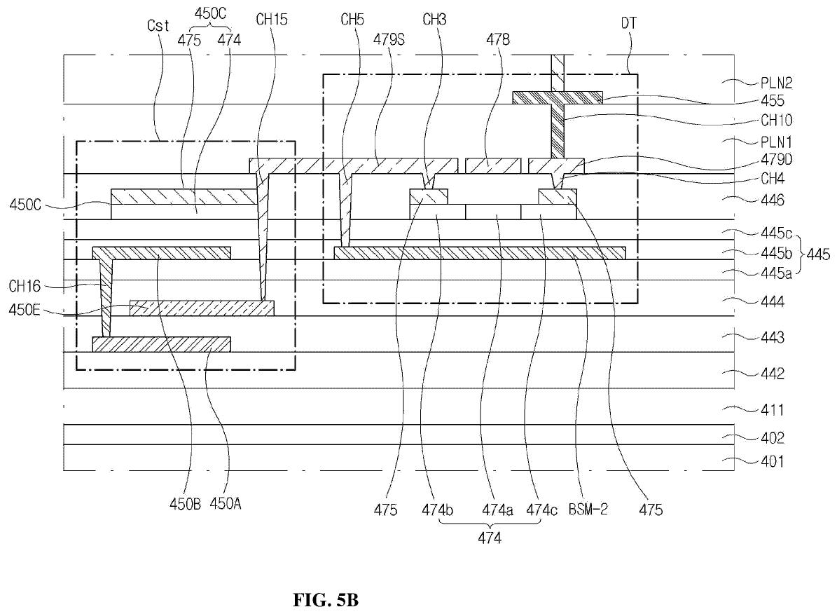

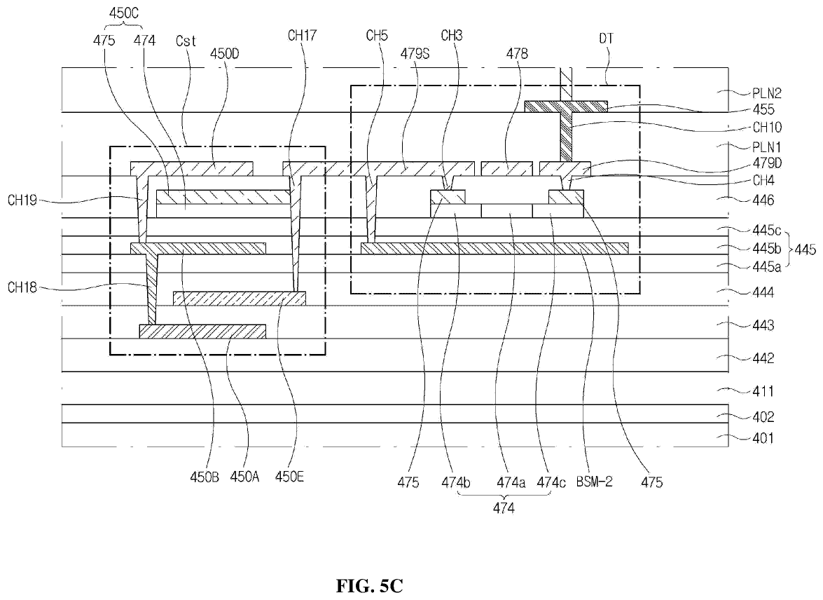

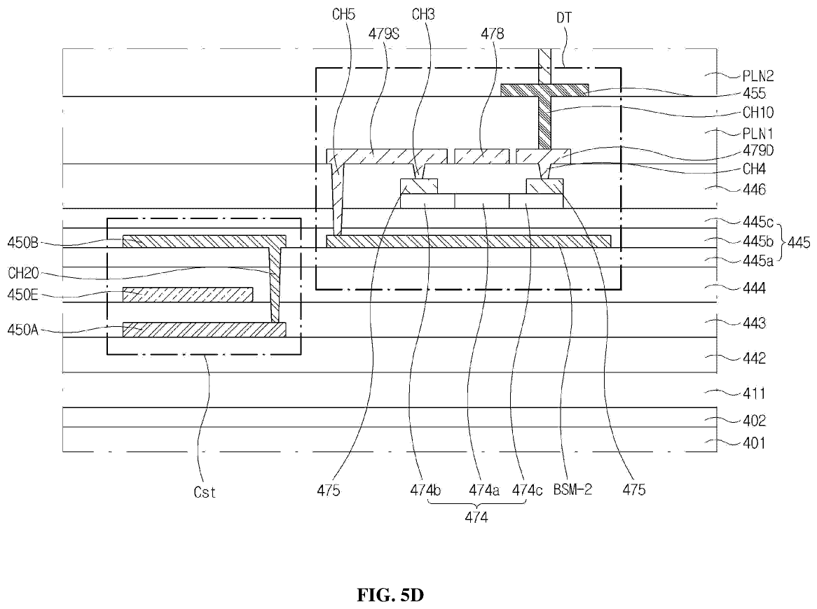

Meanwhile, referring to FIG. 5A, an organic light emitting display device in which the conductive pattern 475 is not disposed over the first polycrystalline semiconductor pattern 414 is proposed in the present disclosure.

In the embodiment of the present disclosure referring to FIGS. 4A to 4F, the first contact hole CH1 to the ninth contact hole CH9 may be formed through one mask process to reduce mask processes. Since the first contact hole CH1 is deeper than the third to ninth contact holes CH3 to CH9 even in the the embodiment shown in FIG. 4A, the first polycrystalline semiconductor pattern 414 under the first contact hole CH1 may be damaged due to long exposure to an etching gas.

The embodiment of the present disclosure referring to FIG. 5A proposes an organic light emitting display device in which the first polycrystalline semiconductor pattern 414 is not damaged during a process of forming a contact hole.

Referring to FIG. 5A, a driving thin film transistor DT disposed in a sub-pixel is the same as that of the embodiment disclosed in FIG. 4A. However, the configuration of the first thin film transistor GT disposed in the non-display area NA may be partially different from that of the embodiment disclosed in FIG. 4A, and the configuration of the switching thin film transistor ST-1 may also be partially different from that of the embodiment disclosed in FIG. 4A.

The configurations of the first polycrystalline semiconductor pattern 414, the first gate electrode 416, and the first light blocking pattern BSM-1 of the first thin film transistor GT are the same as those of FIG. 4A.

It is noted that the first source electrode 417S and the first drain electrode 417D of the first thin film transistor GT may be disposed in a lower layer than the second source electrode 479S and the second drain electrode 479D.

Since the first source electrode 417S, the first drain electrode 417D, and the second light blocking pattern BSM-2 are disposed in the same layer, the first source electrode 417S, the first drain electrode 417D, and the second light blocking pattern BSM-1 may be simultaneously made of the same material. That is, they may be formed through one mask process.

Accordingly, the first contact hole CH1 and the second contact hole CH2 may be formed earlier than the third to seventh contact holes CH3 to CH7.

Since the first contact hole CH1 and the second contact hole CH2 are formed through a separate mask process to expose the first polycrystalline semiconductor pattern 414, optimum etching conditions may be set such that the first polycrystalline semiconductor pattern 414 is not damaged.

Meanwhile, when the first switching thin film transistor ST-1 constitutes a dual gate, the third gate electrode 433 and the third light blocking pattern BSM-3 may be electrically connected. In this case, the third gate electrode 433 and the third light blocking pattern BSM-3 may be connected to each other through a thirteenth contact hole CH13 and a fourteenth contact hole CH14.

In addition, a bridge metal BM may be provided between the thirteenth contact hole CH13 and the fourteenth contact hole CH14. The bridge metal BM may be made of the same material as the second light blocking pattern BSM-2 and may be disposed in the same layer as the second light blocking pattern BSM-2.

The thirteenth contact hole CH13 formed under the bridge metal BM may be formed simultaneously with the first contact hole CH1 and the second contact hole CH2.

Accordingly, in the embodiment of the present disclosure referring to FIG. 5A, the first contact hole CH1, the second contact hole CH2, and the thirteenth contact hole CH13 may be simultaneously formed. Also, when the second light blocking pattern BSM-2 is formed on the first sub-upper buffer layer 445a, the first source electrode 417S, the first drain electrode 417D, and the bridge metal BM may be simultaneously formed, thus reducing the mask processes.

In addition, the third gate electrode 433 may be connected to the bridge metal BM through the fourteenth contact hole CH14 and connected to the third light blocking pattern BSM-3 by passing through the bridge metal BM, thereby forming a dual gate.

In the embodiment of the present disclosure shown in FIG. 5A, the first switching thin film transistor ST-1 is an oxide semiconductor thin film transistor having a dual gate, but the first switching thin film transistor ST-1 does not necessarily have a dual gate structure. That is, the configuration of the gate electrode may be selective. That is, when only one gate is provided, the third light blocking pattern BSM-3 and the bridge metal BM may be unnecessary.

In addition, in the embodiment disclosed in FIG. 5A, the third to seventh contact holes CH3 to CH7 and the twelfth contact hole CH12 have different depths, but are formed simultaneously because the third to seventh contact holes CH7 and the twelfth contact hole CH12 have metal patterns under the contact holes.

Although not shown in the drawings, in the embodiment shown in FIG. 5A, the etching of the inorganic insulating film in the bezel bending area BA may be different from the case illustrated in FIG. 4C. That is, in the embodiment illustrated in FIG. 5A, when the first contact hole CH1, the second contact hole CH2, and the thirteenth contact hole CH13 are formed, the first lower buffer layer 402, the second lower buffer layer 411, the first gate insulating layer 442, the first interlayer insulating layer 443, the second interlayer insulating layer 444, and the first sub-upper buffer layer 445a which are deposited in the bezel bending area BA may be etched simultaneously. Also, when the third to seventh contact holes CH3 to CH7, the twelfth contact hole CH12, and the fourteenth contact hole CH14 are formed, the second sub-upper buffer layer 445b, the third sub-upper buffer layer 445c and the second gate insulating layer 446 which are deposited on the bezel bending area BA may be etched.

Meanwhile, in the embodiment of the present disclosure illustrated in FIG. 5A, the storage capacitor Cst may have a structure different from that of the storage capacitor Cst illustrated in FIG. 4A.

Referring to FIG. 5A, a storage capacitor Cst may include a first electrode 450A of the storage capacitor disposed in the same layer as the first gate electrode 416, a second electrode 450B of the storage capacitor formed in the same layer as the second light blocking pattern BSM-2, and a third electrode 450C of the storage capacitor in which an oxide semiconductor pattern and a metal pattern disposed in the same layer as the conductive pattern 475 are stacked. Also, the first electrode 450A of the storage capacitor and the third electrode 450C of the storage capacitor are electrically connected to each other, and the second electrode 450B of the storage capacitor is disposed between the two electrodes, so that the sub-capacitances occurring between the electrodes of the storage capacitor adjacent to each other are connected in parallel with each other.

The first electrode 450A of the storage capacitor and the third electrode 450C of the storage capacitor are connected through a twelfth contact hole CH12. In addition, the third electrode 450C of the storage capacitor may be in side contact with the twelfth contact hole CH12 to reduce mask processes.

Meanwhile, another configuration of a storage capacitor Cst applicable to the embodiment of FIG. 5A will be described with reference to FIGS. 5B to 5D in which area B of FIG. 5A is enlarged.

Referring to FIG. 5B, the storage capacitor Cst may further include a fifth electrode 450E of the storage capacitor, which may be a separate metal pattern, between the first electrode 450A of the storage capacitor and the second electrode 450B of the storage capacitor. Also, the first electrode 450A of the storage capacitor and the second electrode 450B of the storage capacitor are electrically connected to each other, and the third electrode 450C of the storage capacitor and the fifth electrode 450E of the storage capacitor are electrically connected to each other. As a result, sub-capacitances are formed between the electrodes of the storage capacitor and the adjacent electrodes of the storage capacitor and are connected in parallel with each other.

Referring to FIG. 5B, the first electrode 450A of the storage capacitor and the second electrode 450B of the storage capacitor may be connected to each other through a sixteenth contact hole CH16, and the third electrode 450C of the storage capacitor and the fifth electrode 450E of the storage capacitor may be connected to each other through a fifteenth contact hole CH15.

Also, the third electrode 450C of the storage capacitor may be in side contact with the fifteenth contact hole CH15 to reduce mask processes.

The fifth electrode 450E of the storage capacitor may be one electrode of the storage capacitor Cst to increase the total capacitance and may be used to form link lines to increase the degree of freedom for line formation

Also, the sixteenth contact hole CH16 may be formed simultaneously with the first contact hole CH1, and the fifteenth contact hole CH15 may be formed simultaneously with the third contact hole CH3. As a result, the number of masks used to form contact holes may be reduced.

Meanwhile, referring to FIG. 5C, the storage capacitor Cst may further include a fourth electrode 450D of the storage capacitor disposed in the same layer as the second gate electrode 478.

Referring to FIG. 5C, the storage capacitor Cst may include a first electrode 450A of the storage capacitor disposed in the same layer as the first gate electrode 416, a second electrode 450B of the storage capacitor disposed in the same layer as the second light blocking pattern BSM-2, a third electrode 450C of the storage capacitor having a stacked structure in which an oxide semiconductor pattern and a metal pattern disposed in the same layer as the conductive pattern 475 are stacked, a fourth electrode 450D of the storage capacitor disposed in the same layer as the second gate electrode 478, and a fifth electrode 450E of the storage capacitor disposed between the first electrode 450A of the storage capacitor and the second electrode 450B of the storage capacitor.

The first electrode 450A of the storage capacitor and the second electrode 450B of the storage capacitor may be connected to each other through an eighteenth contact hole CH18. The second electrode 450B of the storage capacitor may be connected to the fourth electrode 450D of the storage capacitor through a nineteenth contact hole CH19. That is, the first electrode 450A of the storage capacitor, the second electrode 450B of the storage capacitor, and the fourth electrode 450D of the storage capacitor may be electrically connected to each other to be equipotential.

Also, the third electrode 450C of the storage capacitor may be electrically connected to the fifth electrode 450E of the storage capacitor through a seventeenth contact hole CH17.

As a result, the electrodes of each storage capacitor may form sub-storage capacitances with the adjacent electrodes thereof, and the sub-storage capacitances may be connected in parallel to each other to increase the total capacitance of the storage capacitor Cst.

Referring to FIG. 5C, the contact hole CH18 may be formed at the same time as the first contact hole CH1, and the seventeenth contact hole CH17 and the nineteenth contact hole CH19 may be formed at the same time when the third contact hole CH3 is formed.

Also, the third electrode 450C of the storage capacitor may be in side contact with the seventeenth contact hole CH17. As a result, it may contribute to simplifying a process by reducing the number of masks used when forming contact holes.

Meanwhile, referring to FIG. 5D, the storage capacitor Cst according to the present disclosure may be formed without including the conductive pattern 475.

As an example, referring to FIG. 5D, the storage capacitor Cst may include a first electrode 450A of the storage capacitor, a second electrode 450B of the storage capacitor connected to the first electrode 450A of the storage capacitor through a twentieth contact hole CH20, and a fifth electrode 450E of the storage capacitor disposed between the first electrode 450A and the second electrode 450B.

In the above embodiments, the sixteenth contact hole CH16, the eighteenth contact hole CH18, and the twentieth contact hole CH20 may be formed simultaneously when the first contact hole CH1 is formed.

That is, when the first contact hole CH1 is formed to pass through the first gate insulating layer 442, the first interlayer insulating layer 443, the second interlayer insulating layer 444 and the first sub-upper buffer layer 445a which are disposed on the first polycrystalline semiconductor pattern 414 after the first sub-upper buffer layer 445a is deposited, the sixteenth contact hole CH16 of FIG. 5B, the eighteenth contact hole CH18 of FIG. 5C, and the twentieth contact hole CH20 of FIG. 5D, which are disposed on the first electrode 450A of the storage capacitor and have the same depth may be simultaneously formed. The first contact hole CH1 and the sixteenth contact hole CH16 have different depths, but the first electrode 450A of the storage capacitor made of a metal material having stronger corrosion resistance than the inorganic insulating layer may be disposed under the sixteenth contact hole CH16, the eighteenth contact hole CH18, and the twentieth contact hole CH20, so that the first contact hole CH1 may be easily formed.

In addition, since metal patterns having more excellent etching resistance than the inorganic insulating film are disposed under the third contact hole CH3 to seventh contact hole CH7, the twelfth contact hole CH12, the fourteenth contact hole CH14, the fifteenth contact hole CH15, the seventeenth contact hole CH17, the nineteenth contact holes CH19, making it easy to form the contact holes at the same time even when the etching depths are different.

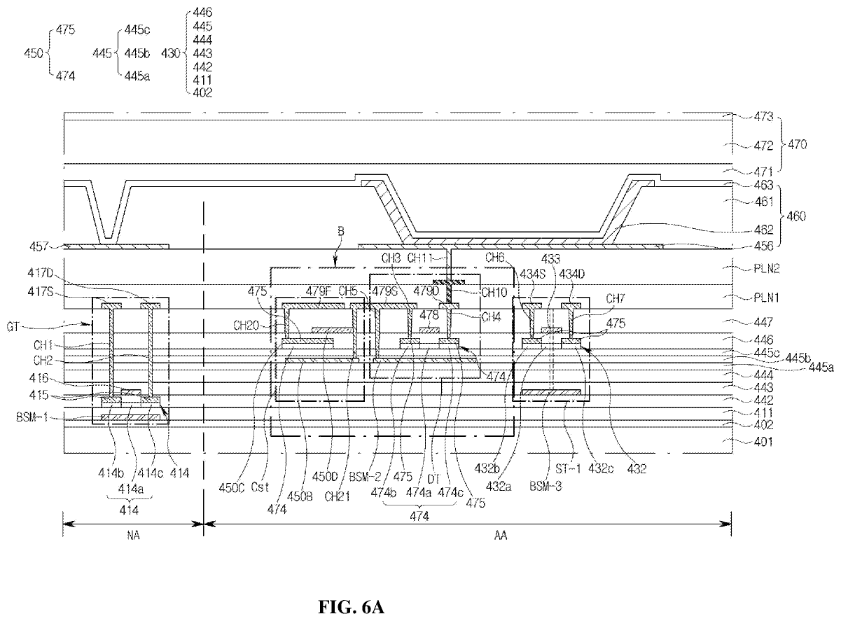

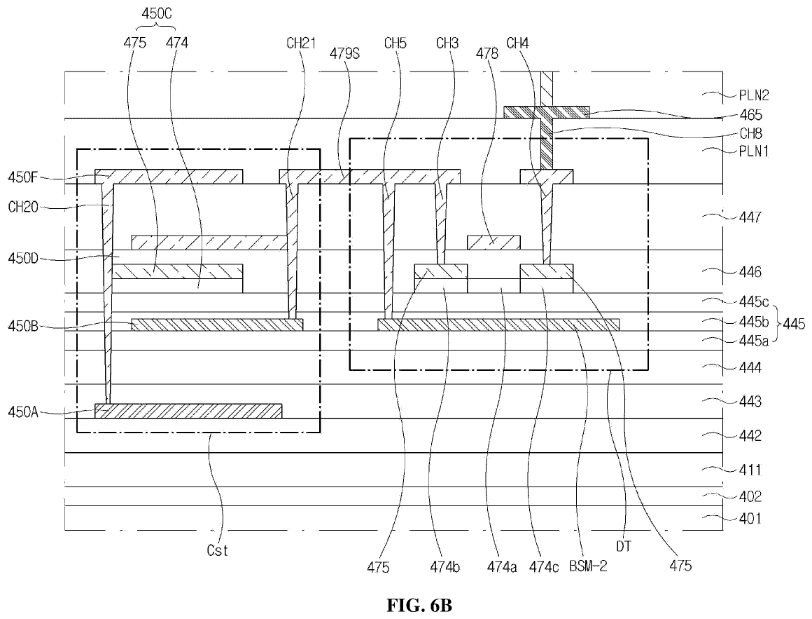

Meanwhile, referring to FIG. 6A, another embodiment of the present disclosure will be described below.

Referring to FIG. 4A, in the driving thin film transistor DT of the present disclosure, the second gate electrode 478, the second source electrode 479S, and the second drain electrode 479D are disposed in the same layer. On the other hand, referring to FIG. 6A, in the driving thin film transistor DT of the present disclosure, the second gate electrode 478, the second source electrode 479S, and the second drain electrode 479D are disposed in different insulating layers.

When the second gate electrode 478, the second source electrode 479S, and the second drain electrode 479D are disposed in the same layer, mask processes may be reduced, but a short circuit may occur between electrodes. Accordingly, in the embodiment referring to FIG. 6A, the second gate electrode 478, the second source electrode 479S, and the second drain electrode 479D are disposed in different insulating layers to prevent or at least reduce a likelihood of a short circuit. Also, the configuration of the storage capacitor may be changed according to the change in the structure of the driving thin film transistor DT.

Referring to FIG. 6A, since the first thin film transistor GT disposed in a gate driver is the same as that described in FIG. 4A, a description thereof is omitted or briefly provided.

In addition, configurations of the driving thin film transistor DT and the first switching thin film transistor ST-1 are identical to those of the embodiment illustrated in FIG. 4A, except for arrangement structures of a gate electrode, a source electrode, and a drain electrode. The differences are mainly described below.

Referring to FIG. 6A, the third interlayer insulating layer 447 may be disposed on the second gate electrode 478. The third interlayer insulating layer 447 is an inorganic insulating layer, and may be configured as a silicon oxide film or the like. The second source electrode 479S and the second drain electrode 479D may be disposed on the third interlayer insulating layer 447. In addition to the second source electrode 479S and the second drain electrode 479D, the third source electrode 434S and the third drain electrode 434D of the first switching thin film transistor ST-1 may be also formed on the third interlayer insulating layer 447.

The first source electrode 417S, the second source electrode 479S, and the third source electrode 434S may all be disposed on the third interlayer insulating layer 447 and manufactured using one mask process.

Also, after the third interlayer insulating layer 447 is deposited, the first contact hole CH1 to the seventh contact hole CH7 may be simultaneously formed through one mask process.

Referring to FIG. 6A, metal patterns are disposed under the first contact hole CH1 to the seventh contact hole CH7, so that it is possible to form contact holes through a single mask process although the depths of the first contact hole CH1 to the seventh contact hole CH7 are different from each other.

Referring to FIG. 6A, since the second gate electrode 478, the second source electrode 479S, and the second drain electrode 479D are positioned in different insulating layers, the second source electrode 479S and the second drain electrode 479D may be designed freely without the risk of a short circuit with the second gate electrode 478.

On the other hand, the storage capacitor Cst may be formed using a second gate electrode material and a second source electrode material disposed in different insulating layers.

Referring to FIG. 6A, the storage capacitor Cst may include a second electrode 450B of the storage capacitor disposed in the same layer as the second light blocking pattern BSM-2, a third electrode 450C of the storage capacitor disposed in the same layer as the first oxide semiconductor pattern 474 and the conductive pattern 475 stacked on each other, a fourth electrode 450D of the storage capacitor disposed in the same layer as the second gate electrode 478, and a sixth electrode 450F of the storage capacitor disposed in the same layer as the second source electrode 479S.

The second electrode 450B of the storage capacitor and the fourth electrode 450D of the storage capacitor may be electrically connected to each other through a twenty-first contact hole CH21, and the third electrode 450C of the storage capacitor and the sixth electrode 450F of the storage capacitor may be electrically connected to each other through a twentieth contact hole CH20, thus increasing the total capacitance of the storage capacitor.

The twentieth contact hole CH20 and the twenty-first contact hole CH21 may be formed simultaneously with the first to seventh contact holes CH1 to CH7.

In addition, the fourth electrode 450D of the storage capacitor may be in side contact with the twenty-first contact hole CH21 to reduce the mask processes. As the fourth electrode 450D of the storage capacitor comes into side contact with the twenty-first contact hole CH21, the fourth electrode 450D of the storage capacitor may be connected to the second electrode 450B of the storage capacitor through only one twenty-first contact hole CH21.

Meanwhile, referring to FIG. 6B, the storage capacitor Cst may further include the first electrode 450A of the storage capacitor.

FIG. 6B is an enlarged view of area B of FIG. 6A according to one embodiment of the present disclosure, and another configuration of the storage capacitor Cst will be described with reference to FIG. 6B.

The storage capacitor Cst illustrated in FIG. 6B may further include the first electrode 450A of the storage capacitor in addition to the configuration of the storage capacitor Cst illustrated in FIG. 6A. Further, the first electrode 450A of the storage capacitor, the third electrode 450C of the storage capacitor, and the sixth electrode 450F of the storage capacitor may be connected to each other through the twentieth contact hole CH20, and the second electrode 450B of the storage capacitor and the fourth electrode 450D of the storage capacitor may be connected to each other through the twenty-first contact hole CH21. As a result, each electrode of the storage capacitor may form a sub-storage capacitor with an electrode adjacent thereto and the sub-storage capacitors are connected in parallel to each other, so that the total capacitance may increase.

In addition, the fourth electrode 450D of the storage capacitor may be in side contact with the twenty-first contact hole CH21 so that the fourth electrode 450D may be connected to the second electrode 450B of the storage capacitor while reducing mask processes.

In the above, various configurations of the pixel circuit portion 430 according to the embodiments of the present disclosure have been described.

Referring to FIG. 4A, a first planarization layer PLN1 may be formed on the pixel circuit portion 430. A first planarization layer PLN1 may be made of an organic material such as photoacrylic, but may include a plurality of layers including an inorganic layer and an organic layer. A connection electrode 455 may be formed on the first planarization layer PLN1. The connection electrode 455 may connect the anode electrode 456, which is one component of the light emitting element portion 460, and the driving thin film transistor DT through the tenth contact hole CH10 formed in the first planarization layer PLN1.

In addition, the conductive film used when forming the connection electrode 455 may constitute a part of another link line 452 in the bending area BA.

The second planarization layer PLN2 may be formed on the connection electrode 455. Line the first planarization layer PLN1, the second planarization layer PLN2 may be made of an organic material such as photoacrylic, but may be comprised of a plurality of layers including an inorganic layer and an organic layer.

An anode electrode 456 may be formed on the second planarization layer PLN2. The anode electrode 456 may be electrically connected to the connection electrode 455 through the eleventh contact hole CH11 formed in the second planarization layer PLN2.

The anode electrode 456 is comprised of a single layer or a plurality of layers made of a metal such as Ca, Ba, Mg, Al, Ag, or alloys thereof and is connected to the second drain electrode 479D of the driving thin film transistor DT, so that an image signal is applied to the anode electrode 456 from the outside.

In addition to the anode electrode 456, an anode connection electrode 457 that electrically connects a common voltage line VSS and a cathode electrode 463 may be further provided in the non-display area NA.

A bank layer 461 may be formed on the second planarization layer PLN2. The bank layer 461, as a kind of barrier rib, separates sub-pixels to reduce or prevent light of a specific color output from adjacent sub-pixels from being mixed and output.

An organic light emitting layer 462 may be formed on the surface of the anode electrode 456 and on a portion of the inclined surface of the bank layer 461. The organic light emitting layer 462 may be formed in each sub-pixel and may be an R-organic light emitting layer that emits red light, a G-organic light emitting layer that emits green light, and a B-organic light emitting layer that emits blue light. Also, the organic light emitting layer 462 may be a W-organic light emitting layer that emits white light.

The organic light emitting layer 462 may include not only the light emitting layer, but also an electron injection layer and a hole injection layer respectively injecting electrons and holes into the light emitting layer, and an electron transport layer and a hole transport layer respectively transporting the injected electrons and holes to an organic layer.

A cathode electrode 463 may be formed on the organic light emitting layer 462. The cathode electrode 463 may be made of a transparent conductive material such as indium tin oxide (ITO) or indium zinc oxide (IZO) or a thin metal through which visible light is transmitted, but is not limited thereto.

An encapsulation layer 470 is formed on the cathode electrode 463. The encapsulation layer 470 may include a single layer of an inorganic layer, may include two layers of an inorganic layer and an organic layer, or may include three layers of an inorganic layer, an organic layer and an inorganic layer. The inorganic layer may be made of inorganic materials such as SiNx and SiOx, but is not limited thereto. In addition, the organic layer may be made of an organic material such as polyethylene terephthalate, polyethylene naphthalate, polycarbonate, polyimide, polyethylene sulfonate, polyoxymethylene, polyarylate, or a mixture thereof, but is not limited thereto.

FIG. 4A illustrates the encapsulation layer 470 including three layers of an inorganic layer 471/an organic layer 472/an inorganic layer 473 as an example.

A cover glass (not shown) may be disposed on the encapsulation layer 470 and attached to the encapsulation layer 470 by an adhesive layer (not shown). As the adhesive layer, any material may be used as long as it has good adhesion and good heat resistance and water resistance, but in the present disclosure, a thermosetting resin such as an epoxy-based compound, an acrylate-based compound, or an acrylic rubber may be used. In addition, a photocurable resin may be used as the adhesive, and in this case, the adhesive layer is cured by irradiating light such as ultraviolet rays to the adhesive layer.

The adhesive layer may not only bond the substrate 401 and a cover glass (not shown), but also serves as an encapsulant for reducing or preventing moisture from penetrating into the organic light emitting display device.

The cover glass (not shown) is an encapsulation cap for encapsulating the organic light emitting display device, and as the cover glass, a protective film such as a polystyrene (PS) film, a polyethylene (PE) film, a polyethylene naphthalate (PEN) film, or a polyimide (PI) film may be used, and glass may be used.

The above description and accompanying drawings are merely illustrative of the technical idea of the present disclosure, and various modifications and variations, such as combination, separation, substitution and change of configurations, may be made without departing from the essential characteristics of the present disclosure by those skilled in the art to which the present disclosure pertains. Therefore, the embodiments of the present disclosure are provided for illustrative purposes only but not intended to limit the technical spirit of the present disclosure, and the scope of the technical idea of the present disclosure is not limited by these embodiments. The scope of protection of the present disclosure should be interpreted by the following claims, and all technical ideas within the scope equivalent thereto should be construed as being included in the scope of the present disclosure.

What is claimed is:

1. An organic light emitting display device comprising:
a substrate including a display area and a non-display area in a vicinity of the display area;
an upper buffer layer on the substrate;
a first thin film transistor including a first semiconductor pattern and a first gate electrode, the first semiconductor pattern under the upper buffer layer;
a second thin film transistor including a second semiconductor pattern and a second gate electrode, the second semiconductor pattern above the upper buffer layer;
a conductive pattern above at least one of the first semiconductor pattern and the second semiconductor pattern; and
a storage capacitor connected to the second thin film transistor.

2. The organic light emitting display device of claim 1, wherein the second thin film transistor comprises a second source electrode and a second drain electrode disposed above the upper buffer layer, and a second light blocking pattern is below the second semiconductor pattern and is connected to one of the second source electrode and the second drain electrode.

3. The organic light emitting display device of claim 2, wherein the second light blocking pattern is in the upper buffer layer,
wherein the second gate electrode is above the second semiconductor pattern with a second gate insulating layer interposed therebetween, and
wherein a parasitic capacitance between the second light blocking pattern and the second semiconductor pattern is greater than a parasitic capacitance between the second gate electrode and the second semiconductor pattern.

4. The organic light emitting display device of claim 1, wherein the first thin film transistor is in one of the display area and the non-display area, and
wherein the second thin film transistor is in the display area.

5. The organic light emitting display device of claim 4, wherein the first semiconductor pattern comprises a polycrystalline semiconductor pattern, and the second semiconductor pattern comprises an oxide semiconductor pattern.

6. The organic light emitting display device of claim 3, wherein a first sub-upper buffer layer constituting a part of the upper buffer layer is under the second light blocking pattern, and a second sub-upper buffer layer constituting a part of the upper buffer layer is above the second light blocking pattern.

7. The organic light emitting display device of claim 2, wherein the storage capacitor comprises:
a first electrode of the storage capacitor in a same layer as the first gate electrode;
a second electrode of the storage capacitor in a same layer as the second light blocking pattern; and
a third electrode of the storage capacitor in a same layer as the conductive pattern.

8. The organic light emitting display device of claim 7, wherein the storage capacitor further comprises a fourth electrode of the storage capacitor in a same layer as the second gate electrode.

9. The organic light emitting display device of claim 8, wherein the storage capacitor further comprises a fifth electrode of the storage capacitor between the first electrode of the storage capacitor and the second electrode of the storage capacitor.

10. The organic light emitting display device of claim 7, wherein the storage capacitor further comprises a fifth electrode of the storage capacitor between the first electrode of the storage capacitor and the second electrode of the storage capacitor.

11. The organic light emitting display device of claim 2, wherein the storage capacitor further comprises:
a second electrode of the storage capacitor in a same layer as the second light blocking pattern;
a third electrode of the storage capacitor in a same layer as the conductive pattern;
a fourth electrode of the storage capacitor in a same layer as the second gate electrode; and
a sixth electrode of the storage capacitor in a same layer as the second source electrode.

12. The organic light emitting display device of claim 11, wherein the storage capacitor further comprises a first electrode of the storage capacitor in a same layer as the first gate electrode.

13. The organic light emitting display device of claim 11, wherein the second gate electrode and the second source electrode are in different layers.

14. The organic light emitting display device of claim 7, wherein the second gate electrode and the second source electrode are disposed in a same layer as each other.

15. The organic light emitting display device of claim 10, wherein sub-storage capacitances formed between adjacent electrodes among the first electrode of the storage capacitor to the fifth electrode of the storage capacitor are connected in parallel to each other.

16. The organic light emitting display device of claim 7, wherein electrodes of the storage capacitor other than the first electrode of the storage capacitor are electrically connected to each other.

17. The organic light emitting display device of claim 7, wherein the third electrode of the storage capacitor has a structure in which the second semiconductor pattern and the conductive pattern are stacked.

18. The organic light emitting display device of claim 7, wherein the third electrode of the storage capacitor is connected to another electrode of the storage capacitor through a contact hole, and the third electrode of the storage capacitor is in contact with a side of the contact hole.

19. The organic light emitting display device of claim 1, wherein the first thin film transistor comprises a first source electrode and a first drain electrode,
wherein the second thin film transistor comprises a second source electrode and a second drain electrode,
wherein the first source electrode, the first drain electrode, the second source electrode, the second drain electrode and the second gate electrode are disposed in a same layer.

20. The organic light emitting display device of claim 1, wherein the first thin film transistor comprises a first source electrode and a first drain electrode,
wherein the second thin film transistor comprises a second source electrode and a second drain electrode,
wherein the first source electrode and the first drain electrode are in a same layer as the second light blocking pattern, and
wherein the second source electrode and the second drain electrode are in a same layer as the second gate electrode.

21. The organic light emitting display device of claim 1, wherein the second thin film transistor is configured to drive a unit pixel in the display area.

22. The organic light emitting display device of claim 1, wherein the storage capacitor comprises a first electrode of the storage capacitor in a same layer as the first gate electrode, and a second electrode of the storage capacitor is in a same layer as the second light blocking pattern.

23. The organic light emitting display device of claim 22, wherein the storage capacitor further comprises a fifth electrode of the storage capacitor between the first electrode of the storage capacitor and the second electrode of the storage capacitor.

24. The organic light emitting display device of claim 23, wherein the first electrode of the storage capacitor and the second electrode of the storage capacitor are electrically connected to each other.

25. The organic light emitting display device of claim 23, wherein the second electrode of the storage capacitor is in contact with a side of a contact hole connecting the first electrode of the storage capacitor and the second electrode of the storage capacitor to each other.
